(19) United States
(12) Patent Application Publication
(10) Pub. No.: US 2003/0020565 A1
(43) Pub. Date: Jan. 30, 2003

(54) MEMS resonators and methods for manufacturing MEMS resonators

(75) Inventors: Kenneth D. Cornett, Coral Springs, FL (US); Joseph P. Heck, Fort Lauderdale, FL (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schamburg, IL

(21) Appl. No.: 09/910,799

(22) Filed: Jul. 24, 2001

(51) Int. Cl. H03H 9/24

(52) U.S. Cl. 333/197; 333/198; 333/199

(57) ABSTRACT

Electromechanical resonating devices such as MEMS resonators are provided in semiconductor structures and devices having high-quality monocrystalline semiconductor layers formed by utilizing compliant substrates. The semiconductor layer is patternwise etched to define a vibrational mode resonator member with one or more supports mechanically coupled to the member. A portion beneath the member is etched to provide clearance for vibrational mode operation of the resonating member. The semiconductor layer is selectively doped to define one or more conductive pathways to the resonating member.

### CROSS REFERENCE TO RELATED APPLICATIONS

This application is related to pending U.S. application Ser. No. 09/828,431, filed Apr. 9, 2001, and assigned to Motorola, Inc.

### FIELD OF THE INVENTION

This invention relates generally to semiconductor structures and devices and their fabrication, and more specifically to semiconductor structures and devices utilizing a compliant substrate. The invention relates also to the fabrication and use of Microelectromechanical Systems (MEMS) and more particularly, frequency selective MEMS devices, and methods for integrating MEMS devices with the aforementioned semiconductor structures and devices.

### BACKGROUND OF THE INVENTION

Currently, there is an interest in increasing the degree of integration of electronics. Integration has proceeded steadily over the last few decades and achieved remarkable reduction in the physical size occupied by electronic circuits. Microelectromechanical System (MEMS) based resonators have been proposed as an alternative to bulky quartz resonators for use as frequency selective components for use at RF frequencies. One type of MEMS resonator that has been proposed comprises a suspended beam of semiconductor material that is shaped and sized to resonate at a selected frequency chosen in view of a desired electrical frequency response. The MEMS resonator serves as a frequency selective component in a circuit. According to one design, the MEMS resonator is driven by a drive electrode that extends below the suspended beam.

During the past decade there has been an increased interest in the semiconductor industry in use of Silicon On Insulator (SOI) wafers. SOI wafers include a silicon substrate, a silicon dioxide layer on the silicon substrate, and a single crystal silicon layer on the silicon dioxide layer. SOI wafers afford a number of advantages in terms of the electrical properties of circuits built using them, including reduced voltage requirements, and power consumption for a given clock speed. It would be advantageous to have a MEMS resonator design that is especially suited for implementation on SOI and other types of high quality monocrystalline wafers.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having grown monocrystalline film having the same crystal orientation as an underlying substrate. This monocrystalline material layer may be comprised of a semiconductor material, a compound semiconductor material, and other types of material such as metals and non-metals.

### BRIEF DESCRIPTION OF THE DRAWINGS

The present invention is illustrated by way of example and not limitation in the accompanying figures, in which like references indicate similar elements, and in which:

FIG. 1 is a flow chart of a process for manufacturing a MEMS resonator on a simplified wafer;

FIG. 2 is a sectional elevation view of a wafer used in the process shown in FIG. 1;

FIG. 3 is a sectional elevation view of the wafer shown in FIG. 2 during a first resist exposure operation;

FIG. 4 is a sectional elevation view of the wafer shown in FIG. 3 during a doping operation;

FIG. 5 is a plan view of the wafer shown in FIG. 4 after a doping operation;

FIG. 6 is a sectional elevation view of the wafer shown in FIG. 5 during a second resist exposure operation;

FIG. 7 is a sectional elevation view of the wafer shown in FIG. 6 after a resist development operation;

FIG. 8 is a sectional elevation view of the wafer shown in FIG. 7 after a silicon top layer etching operation;

FIG. 9 is a plan view of the wafer shown in FIG. 7 after the silicon top layer etching operation;

FIG. 10 is a sectional elevation view of the wafer shown in FIG. 9 during a third resist exposure operation;

FIG. 11 is a sectional elevation view of the wafer shown in FIG. 10 after a resist development operation;

FIG. 12 is a sectional elevation view of the wafer shown in FIG. 11 after an oxide etch operation;

FIG. 13 is a broken out perspective view of a wafer showing the integrated MEMS resonator shown in FIG. 12;

FIG. 14 is a broken out perspective view of a wafer showing a second integrated MEMS resonator;

FIG. 15 is a broken out perspective view of a wafer showing a third MEMS resonator;

FIG. 16 is a broken out perspective view of a wafer showing a fourth integrated MEMS resonator for use with an integrated MEMS resonator;

FIG. 17 is a flow chart of a first process of making a wafer for use with an integrated MEMS resonator;

FIG. 18 is a depiction of a silicon wafer used in making a wafer for use with an integrated MEMS resonator;

FIG. 19 is a sectional elevation view of the wafer shown in FIG. 18 after an oxide growth step;

FIG. 20 is a sectional elevation view of the wafer shown in FIG. 19 after a hydrogen implantation step;

FIG. 21 is a sectional elevation view of the wafer shown in FIG. 20 bonded to a second wafer of the type shown in FIG. 18;

FIG. 22 is a wafer obtained by cleaving the wafer shown in FIG. 21;

FIG. 23 is a flow chart of a second process of making a wafer for use with an integrated MEMS resonator;

FIG. 24 is a sectional elevation view of the wafer made by the process shown in FIG. 23;

FIG. 25 is a flow chart of a third process of making a wafer for use with an integrated MEMS resonator;

FIG. 26 depicts sectional elevation views of two wafers used to make the wafer according to the process shown in FIG. 25;

FIG. 27 is a sectional elevation view of a wafer produced by the process shown in FIG. 25;

FIG. 28 is a sectional elevation view of a wafer bearing a first resist that is being exposed to patterning radiation in a process for making a MEMS resonator;

FIG. 29 is a sectional elevation view of the wafer shown in FIG. 28 during a doping operation;

FIG. 30 is a plan view of the wafer shown in FIG. 29 showing doped areas;

FIG. 31 is a sectional elevation view of the wafer shown in FIG. 29 bearing a second resist that is being exposed to patterning radiation;

FIG. 32 is a sectional elevation view of the wafer shown in FIG. 31 after development of the second resist;

FIG. 33 is a sectional elevation view of the wafer shown in FIG. 32 after etching using the second resist;

FIG. 34 is a plan view of a first vertically oriented resonant member MEMS resonator device;

FIG. 35 is a flow chart of a process of making a MEMS resonator;

FIG. 36 is a fragmentary plan view of a MEMS resonator that has vibrating plate oriented perpendicular to a semiconductor chip surface;

FIG. 37 is a sectional elevation view of the MEMS resonator shown in FIG. 36;

FIG. 38 is a fragmentary plan view of a MEMS resonator that has a corrugated trench wall;

FIG. 39 is a fragmentary plan view of a MEMS resonator that includes a vibrating plate with two clamped edges;

FIG. 40 is a fragmentary plan view of a MEMS resonator that includes a vibrating plate with three clamped edges;

FIG. 41 is a schematic of an oscillator using the MEMS resonator shown in FIG. 16;

FIG. 42 is a schematic of an oscillator using the MEMS resonator shown in FIG. 40;

FIGS. 43, 44, and 45 illustrate schematically, in cross section, certain device structures;

FIG. 46 illustrates graphically the relationship between maximum attainable film thickness and lattice mismatch between a host crystal and a grown crystalline overlayer;

FIG. 47 illustrates a high resolution Transmission Electron Micrograph of a structure including a monocrystalline accommodating buffer layer;

FIG. 48 illustrates an x-ray diffraction spectrum of a structure including a monocrystalline accommodating buffer layer;

FIG. 49 illustrates a high resolution Transmission Electron Micrograph of a structure including an amorphous oxide layer;

FIG. 50 illustrates an x-ray diffraction spectrum of a structure including an amorphous oxide layer;

FIGS. 51-54 illustrate schematically, in cross-section, the formation of a device structure;

FIGS. 55-58 illustrate a probable molecular bonding structure of the device structures illustrated in FIGS. 51-54;

FIGS. 59-62 illustrate schematically, in cross-section, the formation of another device structure; and

FIGS. 63-65 illustrate schematically, in cross-section, the formation of yet another embodiment of a device structure.

FIGS. 66, 67, and 68 illustrate the structures described by FIGS. 54, 62, and 65 respectively in a perspective view along with a resonating member patternwise etched into the compound semiconductor layer in accordance with the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION OF THE PREFERRED EMBODIMENTS

While this invention is susceptible of the embodiment in many different forms, there are shown in the drawings and will herein be described in detail specific embodiments, with the understanding that the present disclosure is to be considered as an example of the principles of the present invention and not intended to limit the present invention to the specific embodiments shown and described. Further, the terms and words used herein are not to be considered limiting, but rather merely descriptive. In the description below, like reference numbers are used to describe the same, similar, or corresponding parts in the several views of the drawings.

The present invention is directed to electromechanical resonating devices such as MEMS resonators, presented (that is, integrated with, implemented in, incorporated in, added to or otherwise associated with) semiconductor structures and devices such as integrated circuits, which include a compliant substrate with overlying layers of monocrystalline material comprised of semiconductor material, compound semiconductor material and/or other types of material such as metals and non-metals. In part I following, examples of electromechanical resonating devices embodied in simpler semiconductor structures, preferably “silicon on insulator” or SOI structures are given. SOI structures, e.g., wafers, include a silicon substrate, a silicon dioxide layer on a silicon substrate, and a monocrystalline silicon on the silicon dioxide layer.

As silicon technology has matured, the advantages of semiconductor structures and devices with operationally active layers of monocrystalline material other than silicon have been sought. Difficulties encountered in fabricating devices with the necessary high-quality crystalline properties have hampered prior development efforts. As will be seen in part II, many of these difficulties have been successfully overcome. Part II provides a description of more complex monocrystalline semiconductor structures utilizing compliant substrates, the preferred environment for presenting electromechanical resonating devices. The present invention, as will be seen, goes beyond single crystal silicon layer devices and includes many types of monocrystalline materials other than silicon material. In part III, a discussion of exemplar electromechanical resonating products is given.

I. Electromechanical Resonating Devices

The present invention finds particular application in the field of semiconductor fabrication and particularly semiconductor devices of relatively high density, such as integrated circuits. Electromechanical resonating devices according to principles of the present invention occupy relatively small spaces, making them attractive for use, and particularly integration with, integrated circuits and other semiconductor electronic devices. As will be seen herein, electromechanical resonating devices according to principles of the present invention offer a semiconductor manufacturer several advantages resulting in economical construction. For example, it should be borne in mind that the monocrystalline silicon layer of the SOI implementations described in this part may be readily replaced with monocrystalline materials other than silicon, and particularly the monocrystalline materials of the type set forth in part 11. Implementations of electromechanical resonating devices according to principles of the invention may be directed to the monocrystalline material layer without regard to issues of special fabrication elsewhere in a device. For example, with respect to monocrystalline silicon devices such as SOI wafers, only the silicon layer as it is usually fabricated for conventional purposes is required.

High quality crystalline structures of the type preferred, are well suited to making low power consumption devices. The combination of low cost and low power will enable the further proliferation of high density electronic devices (e.g., low cost wireless communication devices). A MEMS resonator design that requires very little area on a high quality semiconductor die is provided. By reducing the area required for a die for a given device, the number of die that can be fit on a wafer can be increased, and the cost per device can be decreased proportionately.

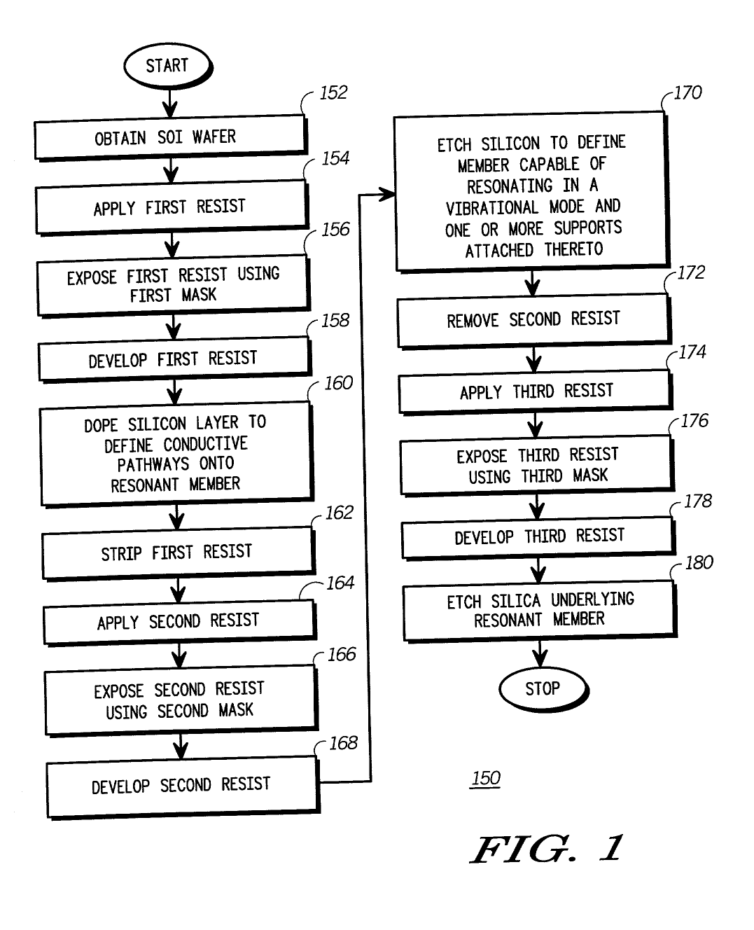

FIG. 1 is a flow chart of a process 150 for manufacturing a MEMS resonator on a SOI wafer according to a preferred embodiment of the invention. In step 152 a SOI type 8 high quality crystalline wafer is obtained. SOI wafers can be produced using a number of manufacturing processes including the UNIBOND TM process, the Separation by Implantation with Oxygen (SIMOX), and the Bond and Etch Back Silicon on Insulator (BESOI) process. These processes are described below in further detail. SOI wafers are available commercially. For example, UNIBOND TM SOI wafers are available commercially from SOITEC USA of Peabody, Mass. SIMOX SOI wafers are available from IBIS corporation of Danvers, Mass.

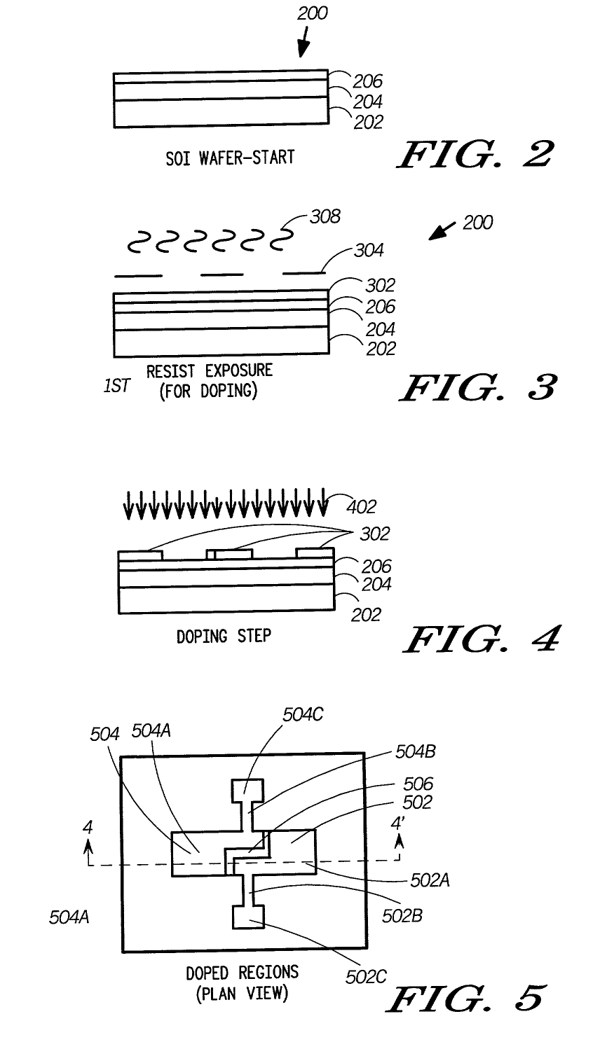

FIG. 2 is a sectional elevation view of a SOI wafer 200 used in the process shown in FIG. 1. (Note that due to the differences in scale between wafers and devices fabricated thereon, the sectional elevation views shown in the figures are not draw to scale.) The SOI wafer 200 comprises a silicon base layer 202, a silicon dioxide layer 204 born on the silicon base layer 202, and a single crystal silicon (device) layer 206 born on the oxide layer 204. The single crystal silicon layers 206 on SOI wafers 200 have a low residual stress. Accordingly, resonator beams can be etched out of the silicon layer 206 without ensuing deformation due to residual stress. Due to the lack of residual stress in the silicon layer 206 lengthy annealing prior to etching is not required. However, annealing may be performed as part of the process of manufacturing the SOI wafer 200.

Referring again to FIG. 1 in step 154 a resist 302 (FIG. 3) is applied to the SOI wafer 200. In a commercial implementation the resist would likely be a photoresist that is suited to UV or X-ray exposure. For prototyping an e-beam resist and e-beam resist patterning is preferred. If needed the resist can be softbaked after it has been applied to evaporate a portion of a solvent component of the resist.

In step 156 the first resist 302 (FIG. 3) is exposed using a first mask 304 (FIG. 3). The first mask 304 (FIG. 3) determines a pattern of doping of the single crystal silicon layer 206.

FIG. 3 is a sectional elevation view of the SOI wafer 200 shown in FIG. 2 during a first resist exposure operation. As shown in FIG. 3, the first resist 302 has been applied to the wafer 200. The wafer 200 can be supported on the stage of a stepper (not shown) proximate to a first exposure mask 304. Radiant or corpuscular energy (e.g., ultraviolet, X-ray or free electrons) 308 is used to image the mask 304 onto the resist 302. The mask 304 can for example, be a phase shift mask in the case that deep ultraviolet is used.

Referring once again to FIG. 1 in step 158 the first resist 302 (FIG. 3) is developed. Optionally the resist can be hard baked after development in preparation for further processing. In step 160 the silicon layer 206 is doped to define conductive pathways onto a resonant member. Note that at this point in the processing the outline of the resonant member has yet to be etched.

FIG. 4 is a sectional elevation view of the SOI wafer shown in FIG. 3 during a doping operation. In FIG. 4 the resist 302 is shown after development in a patterned state. A flux of dopant species (e.g., atoms or ions) 402 is shown above the wafer. Preferably doping is accomplished using an ion implanter, as that is the tool of choice in modern semiconductor fabrication facilities. Alternatively vapor phase doping in a diffusion furnace can be used.

FIG. 5 is a plan view of the SOI wafer 200 shown in FIG. 4 after the doping operation. The location of the section plane of FIG. 4 is indicated in FIG. 5. As seen in FIG. 5, after the doping step 160, the SOI wafer 200 includes a first doped region 502, and a second doped region 504 separated by an non-doped insulating (isolating) region 506. The insulating region can have a low conductivity due to a low dopant concentration. The insulating region can have a sufficient dopant to make its conductivity significant, yet still serve as an isolating region if its dopant is opposite in type (e.g., P as opposed to N) to that used in the first 502 and second 504 doped regions. In the latter case isolation is provided by the presence of at least one reversed biased PN junction between the first 502 and second doped regions, for any voltage difference between the two doped regions 502, 504. The first doped region 502 includes a first sub region 502A that in the completed MEMS resonator will be located on a resonating member, an elongated sub region 502B that in the completed MEMS resonator will lie along a support beam. At the end of the elongated sub region is a pad shaped doped sub region 502C that in the completed MEMS resonator will be located on a perimeter ring that will support the support beam. Similarly the second doped region includes corresponding sub-regions 504A, 504B, and 504C.

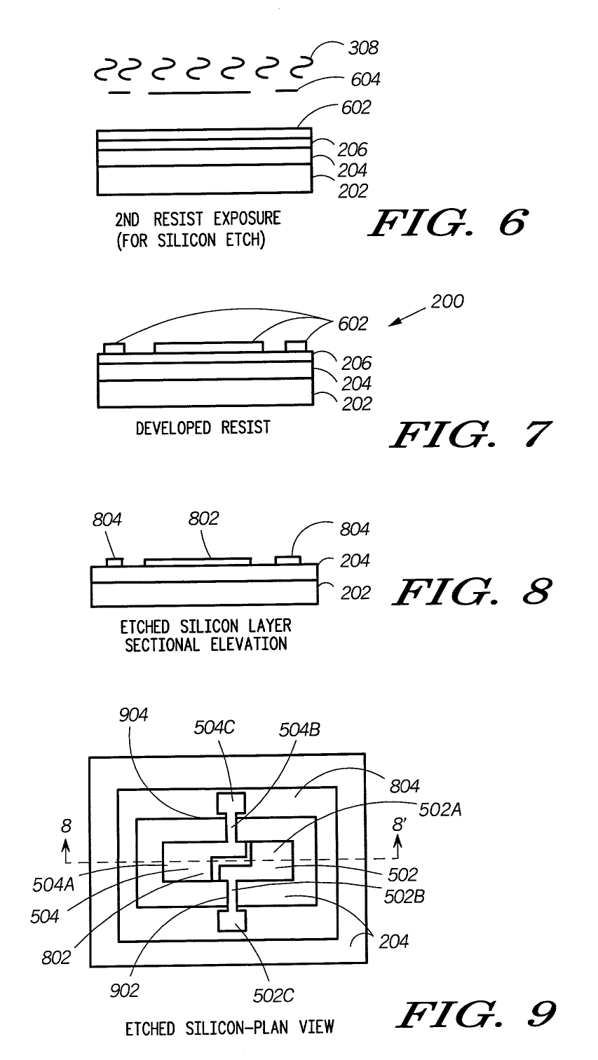

Referring to FIG. 1 in step 162 the first resist 302 is stripped from the SOI wafer 200, and in step 164 a second resist 602 (FIG. 6) is applied to the SOI wafer 200. In step 166 the second resist 602 is imagewise exposed to corpuscular or radiant energy using a second mask 604 (FIG. 6). The second resist 602 defines a pattern for etching the single crystal silicon 206 layer.

In step 168, the second resist layer 602 (FIG. 6) is developed. The developed second resist layer is shown in FIG. 7. In step 170 the single crystal silicon layer 206 is patternwise etched to define a beam shaped member 802 (FIG. 8) capable of resonating in a vibrational mode and one or more supports attached to the member. FIG. 8 is a sectional elevation view showing the resonating member 802, and a perimeter ring 804 that along with a plurality of support beams (not visible in this view) support the resonating member 802.

FIG. 9 is a plan view of the SOI wafer 200 shown in FIG. 7 after the silicon top layer etching operation. As shown in FIG. 9, the first doped sub region 502A and the second doped sub region 504A are located on the resonating member 802, separated by the isolation region 506. The resonating member 802 is seen to be in the form of an elongated beam. The resonating member 802 is attached to the peripheral ring 804 by two support beams 902, 904 which extend perpendicularly from opposite sides of the resonating beam 802 at its longitudinal center. Conducting sub regions 502A, 504A are on the two support beams 902, 904 respectively. The section plane of FIG. 8 is indicated in FIG. 9.

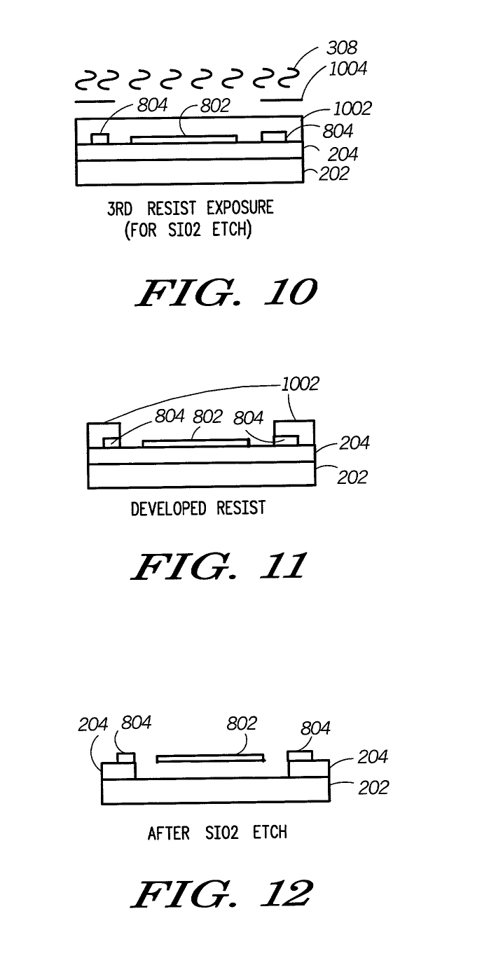

Referring once again to FIG. 1, in step 172 the second resist 602 (FIG. 6) is removed, and in step 174 a third resist 1002 (FIG. 10) is applied. The third resist 1002 (FIG. 10) is used to define an area for etching the oxide layer 204. In step 176 the third resist 1002 (FIG. 10) is exposed to corpuscular or radiant energy 308 (FIG. 3) using a third mask 1004 (FIG. 10). In step 178 the third resist 1002 (FIG. 10) is developed. The third resist 1002 (FIG. 10) is shown after development in FIG. 1. In step 180 the oxide 204 under the resonant member 802, (in fact all of the oxide within the perimeter ring 804) is etched in order to free the resonant member for movement. A Buffered Oxide Etch (BOE) solution is suitable for etching the oxide 214. FIG. 12 is a sectional elevation view of the SOI wafer shown in FIG. 11 after an oxide etch operation. The support beams 902, 904 (FIG. 9) that connect the resonant member 802 to the peripheral ring 804 are not visible in this sectional view (taken along the same lines indicated for FIG. 8 in FIG. 9).

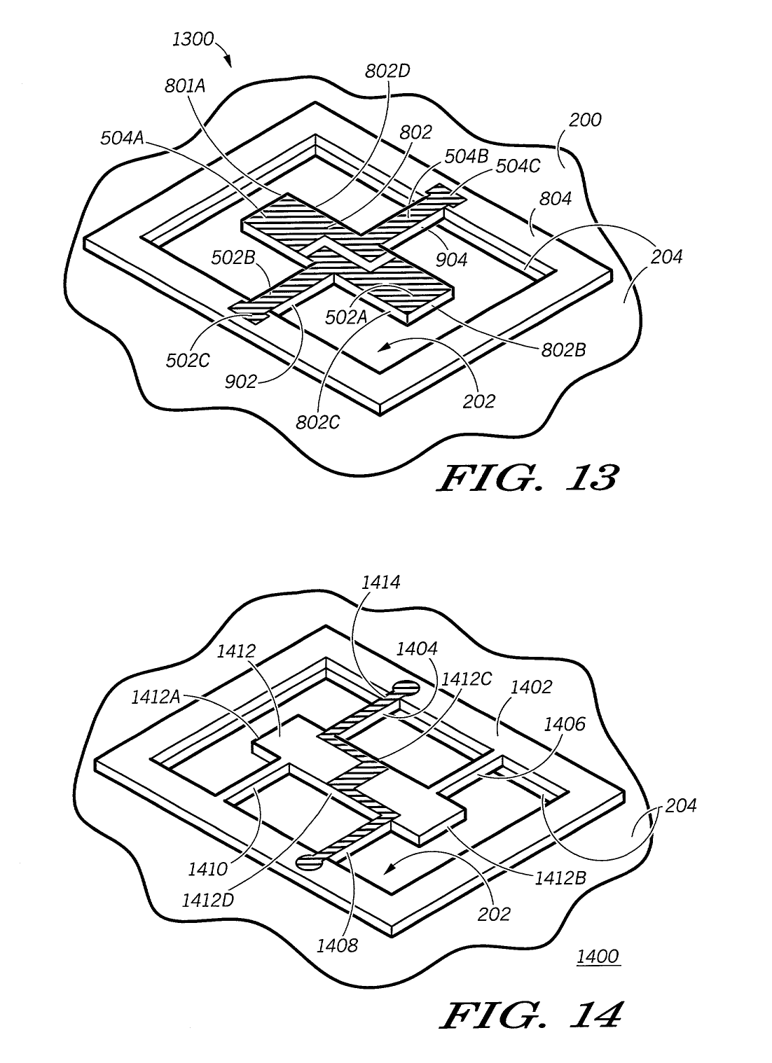

FIG. 13 is a broken out perspective view of the wafer 200 showing the SOI MEMS resonator 1300 fabricated by process 150. The resonant member 802 has a first end 802A, second end 802B, a first peripheral edge 802C extending from the first end 802A to the second end 802B, and a second peripheral edge 802D extending from the first end 802A to the second end 802B. The first 902 and second 904 support beams attached at longitudinal centers of the first 802C and second 802D peripheral edges of the resonant member 802. The first doped region 502 including sub regions 502A, 502B and 502C, and the second doped region 504 including sub regions 504A, 504B and 504C are shown as cross hatched areas. (Doped regions are shown as cross hatched areas in FIGS. 13-16, 30, 34, 36, 38-40. Cross hatched areas in other view may represent different regions as described.) Other parts indicated by reference numeral are described above with reference to the foregoing figures.

FIG. 14 is a broken out perspective view of a wafer showing a second SOI MEMS resonator 1400. The MEMS resonator 1400 comprises a peripheral ring 1402 of single crystal silicon 1402 born on a silicon dioxide layer 204. The silicon dioxide layer 204 is borne on an underlying silicon substrate 202. A single crystal silicon beam shaped resonant member 1412 is centered within the peripheral ring 1402. The beam shaped resonant member has a first end 1412A, a second end 1412B, a first longitudinal edge 1412C extending between the first end 1412A, and the second end 1412B, and a second longitudinal edge 1412D extending between the first end 1412A and the second end 1412B. First 1404, second 1406, third 1408, and fourth 1410 support beams extend between the peripheral ring 1402 and the resonant member 1412. The support beams 1404-1410 are perpendicular to the resonant member 1412. The first 1404 and second 1406 support beams attach to the first longitudinal edge 1412C. The third 1408 and fourth 1410 support beams attach the second longitudinal edge 1412D.

The resonant member 1412 has a size and shape chosen so that it is capable of vibrating in a predetermined mode that has first and second nodes equally spaced from and on opposite sides of a longitudinal center of the beam shaped resonant member 1412. The vibrational mode is a one period sinusoidal flexural mode that is symmetric about the longitudinal center of the beam. The first 1404 and fourth 1410 support beams attach to the resonant member 1412 at the position of the first node of the sinusoid. The second 1406 and third 1408 support beams attach to the resonant member 1412 at the position of the second node of the sinusoid. The center of the beam shaped resonant member is an anti-node of the sinusoid.

A doped region (shown as a cross hatched area) 1414 extends from the peripheral ring 1402, along the first support beam 1404 to the beam shaped resonant member 1412, along the first peripheral edge 1412C toward the longitudinal center of the resonant member 1412, across the resonant member 1412 to the second peripheral edge 1412D, along the second peripheral edge 1412D toward the juncture of the third support beam 1408 and the resonant member 1412, and along the third support beams 1408 back onto the peripheral ring 1402. Portions of the doped region 1414 on the peripheral ring can be used to make a connection between the MEMS resonator 1400 and an external circuit (not shown in this view) such as an oscillator circuit that uses the MEMS resonator to set a resonant frequency. The external circuit can be implemented on the SOI die used to fabricate the MEMS resonator. The external circuit can be implemented using standard methods for integrated circuit fabrication. The connection to the external circuit can be made by an ohmic contact between a metallization plug (not shown) and the doped region 1414 e.g. at the peripheral ring 1402.

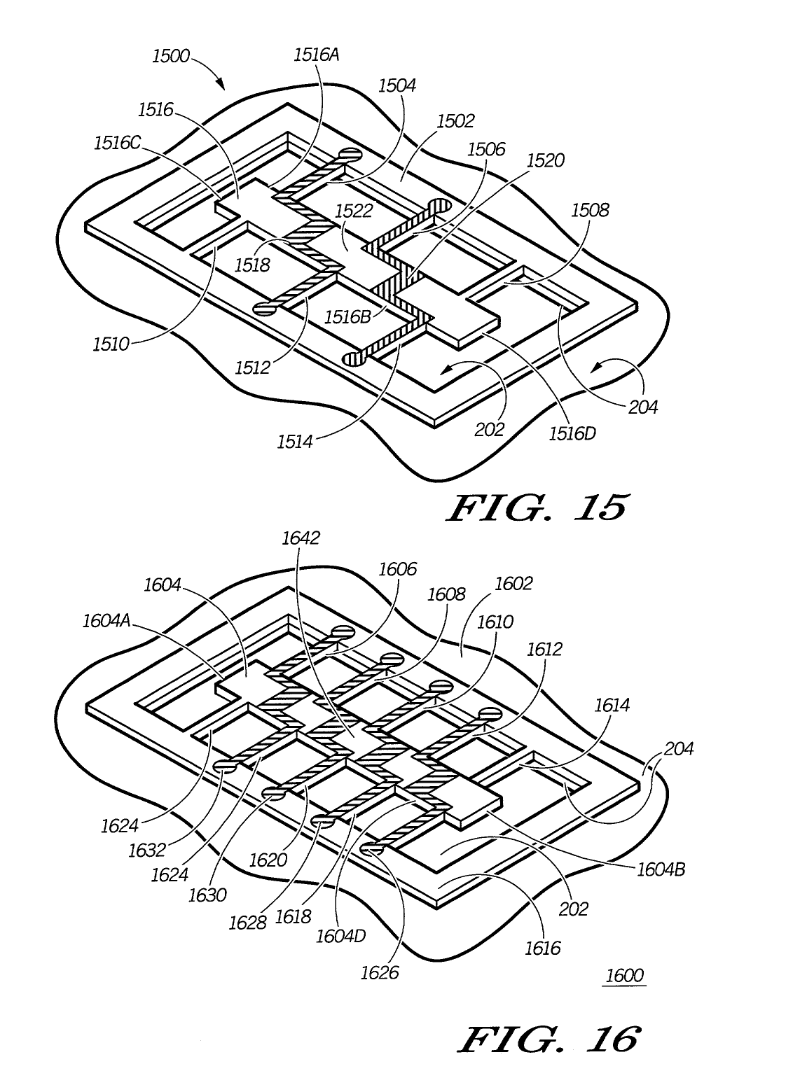

FIG. 15 is a broken out perspective view of a wafer showing a third SOI MEMS resonator 1500. The resonator 1500 includes a beam shaped resonant member 1516. The resonant member 1516 is shaped and sized to vibrate in a one and one-half wavelength sinusoidal flexural beam mode that is anti-symmetric as judged from its longitudinal center. The beam mode includes three nodes, one of which is located at the longitudinal center of the beam, and the other two of which are equally spaced from and on opposite sides of the longitudinal center. The beam mode includes four anti-nodes, two of which are located between the central node and each of the other two nodes, and two of which are located at first and second ends 1516C, and 1516D of the resonant member 1516. The beam shaped resonant member 1516 has, a first longitudinal edge 1516A extending between the first end 1516C and second end 1516D, and a second longitudinal edge 1516B extending between the first end 1516C and the second end 1516D. A first support beam 1504 is connected to the first longitudinal edge 1516A at the position of a first node. A second support beam 1506 is connected to the first longitudinal edge 1516A at the position of the center node. A third support beam 1508 is connected to the first longitudinal edge 1516A at the position of a third node. Fourth through sixth support beams 1510, 1512, 1514 are connected to the second longitudinal edge at the positions of the first, center, and third nodes respectively. The support beams 1504-1514 extend perpendicularly away from the beam shaped resonant member 1516 to a peripheral ring 1502. The beam shaped resonant member 1516, the peripheral ring 1502, and the support beams 1504-1514 are all made from the top silicon layer 206 of a SOI wafer. Within the peripheral ring 1502, the silicon dioxide layer 204 has been etched away to make room for the resonant member 1516 to vibrate.

A first doped region 1518 extends from the peripheral ring 1502, down the length of the first support beam 1504, onto the resonant member 1516, along the first longitudinal edge 1516A in the direction of its longitudinal center to a first anti-node, across the resonant member 1516 at the first anti-node, to the longitudinal center along the second longitudinal edge 1516B, along the fourth support beam 1512 to the peripheral ring 1502. Similarly, a second doped region 1520 extends from the peripheral ring 1502, down the length of the second support beam 1506, onto the resonant member 1516, along the first longitudinal edge 1516A in the direction of the second end 1516D to a second anti-node, across the resonant member 1516 at the second anti-node, along the second longitudinal edge to the node at which the third 1508 and sixth 1514 support beams are connected, along the sixth support beam 1514 to the peripheral ring 1502. Thus the first doped region crosses the resonant member 1516 at first anti-node adjacent to the longitudinal center of the resonant member 1516, and a second doped region crosses the resonant member at a second anti-node adjacent to the longitudinal center of the resonant member 1516. A non-doped isolation region 1522 is located between the first doped region 1518 and the second doped region 1520.

In as much as the resonant mode of the resonant member 1516 is antisymmetric as judged from the center of the resonant member, the two anti-nodes at which the first and second doped regions cross the resonant member 1516 have opposite phase (i.e. when one is deflected up the other is deflected down and visa versa). The resonator 1500 can be caused to resonate by applying opposite polarity signals to the two doped regions 1518 and 1520. The resonator can be used a frequency selective circuit element in a positive feedback loop of an oscillator by connecting one side of the circuit (e.g., from the oscillators amplifier output) to the first conductive region 1518 and a second side of the circuit (e.g. the oscillators amplifiers input) to the second conductive region 1520. Connected as described the resonator 1500 serves a role analogous to that of a quartz crystal resonator.

FIG. 16 is a broken out perspective view of a SOI wafer showing a fourth SOI MEMS resonator 1600. The fourth resonator 1600 includes a beam shaped resonant member 1604 that is sized and shape to oscillate at a predetermined frequency, in a two and one-half period sinusoid flexural beam mode that is anti-symmetric as judged from a center 1642 of member 1604. The resonant member has a first end 1604A, second end 1604B, a first longitudinal edge 1604C extending between the first end 1604A and the second end 1604B, and a second longitudinal edge 1604D extending between the first end 1604A and the second end 1604B. Five support beams extend perpendicularly from the first longitudinal edge 1604C at positions of nodes of the above-mentioned mode. In order, from the first end 1604A to the second end 1604B, the five support beams are identified by reference numerals 1606, 1608, 1610, 1612, and 1614. Similarly five more support beams are attached to the second longitudinal edge 1604D at positions of the nodes. These elements in order from the second end 1604B are labeled by reference numerals 1616, 1618, 1620, 1622, and 1624. The ten support beams 1606-1624 terminate at a peripheral ring 1602. If desired, one or more support beams at one or more node can be eliminated. The resonant device 1600 includes four doped regions 1626, 1628, 1630, and 1632. Each doped region extends from a support beam connected to the first longitudinal edge 1604C over the resonant member 1604, to a support beam connected to the second longitudinal edge 1604D that is offset from the support beam connected to the first longitudinal edge 1604C that shares the same doped region. Each doped region crosses over an anti-node of the resonant mode.

Thus, four anti-nodes are crossed. Adjacent anti-nodes have opposite phases. Every other anti-node has the same phase. The doped regions that cross over anti-nodes that have the same phase can in some embodiments be advantageously connected to an external circuit (e.g., oscillator) in parallel. That is all the doped regions that cross anti-nodes that have one phase can be connected to one side of the circuit, and all the doped regions that cross over anti-nodes with the opposite phase can be connected to the other side of the circuit. By connecting the anti-nodes to an external circuit in parallel, a lower effective impedance for the resonator is realized. This is particularly important in circuits that require lower impedance circuit elements.

Alternatively, the resonator 1600 can be attached to an external circuit as a delay line. To use the resonator 1600 as a delay line, the two doped conductive regions 1632, 1630 near the first end 1604A can be used as differential signal inputs, and the two doped conductive regions 1628 and 1626 near the second end 1604B can be used as differential signal outputs. Alternatively the doped conductive region 1632 closest to the first end 1604A can be used as a single signal input, and the doped conductive region 1626 near the second end 1604B can be used as a single signal output.

Alternatively one pair of oppositely phased conductive regions, e.g., 1626, 1632 can be used as differential inputs of an external circuit, and the other pair of conductive regions, e.g., 1628, 1630 can be used as differential outputs or vice versa. In this configuration the effect of jarring of the resonator 1600 on an output signal will be reduced. This is explained as follows. The resonant member is physically symmetric so that its center of gravity is located at its center 1642. The resonant member 1604 resonates in a mode that is antisymmetric as judged from its center 1642. External jarring will tend to cause the center of the resonant member to deflect up and/or down in a symmetric manner which will cause equal movement of the above-mentioned pairs of oppositely phased doped conductive regions. If for example a differential amplifier with a high common mode rejection ration (CIVIRR) is connected to a pair of oppositely phased doped conductive regions (e.g., 1628, 1630) that are equidistant from the center, the perturbation of the signal caused by the jarring will be rejected by the differential amplifier.

Either for use as a resonator, or as a delay line, the resonator 1600 can be extended so as to resonate in a higher order mode than that shown in FIG. 16.

In each of the embodiments shown in FIGS. 13-16, the peripheral ring 804 (FIGS. 8, 13), 1402 (FIG. 14), 1502 (FIG. 15), 1602 (FIG. 16), the resonant member 802 (FIGS. 8, 13), 1412 (FIG. 14), 1516 (FIG. 15), 1604 (FIG. 16) and the support beams 902-904 (FIGS. 9, 13), 1404-1410 (FIG. 14), 1504-1514 (FIG. 15), 1606-1624 (FIG. 16) are unitary. That is to say that they are all etched from the top silicon layer 206 (FIG. 2) of a SOI wafer 200 (FIG. 2).

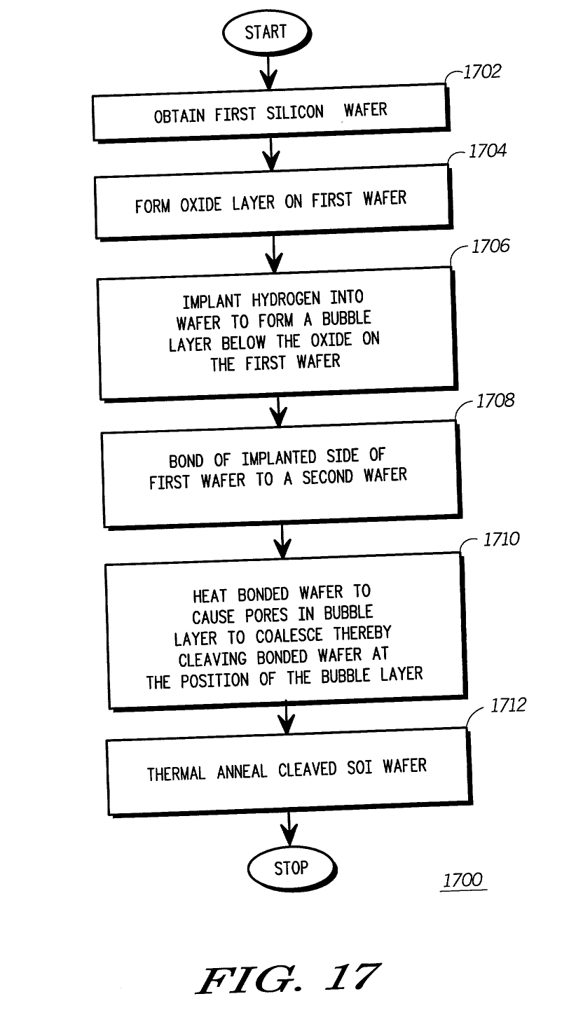

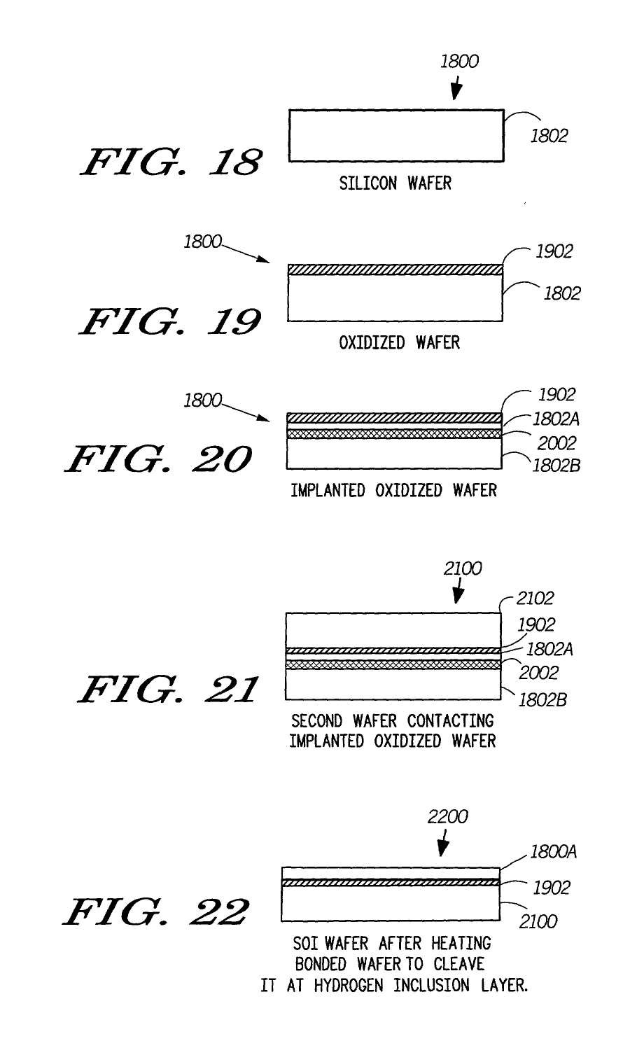

FIG. 17 is a flow chart of a process of making the SOI wafer 200 (FIG. 2) obtained in step 102 (FIG. 1). In step 1702 a first silicon wafer is obtained. FIG. 18 is a depiction of a silicon wafer 1800 used in making a SOI wafer. The wafer includes a disk of silicon 1802. In step 1704 an oxide layer 1902 (FIG. 19) is formed on the silicon disk 1802. The oxide layer 1902 (FIG. 19) is preferably thermally grown. FIG. 19 is a sectional elevation view of the oxidized wafer 1800. The wafer 1800 has a top layer of oxide 1902. The oxide layer 1902 may in fact cover the bottom of the wafer 1800 but a bottom layer of oxide is not critical. In step 1706 hydrogen is implanted into the oxidized wafer at a predetermined average penetration depth below the oxidized layer 1902. FIG. 20 is sectional elevation view of the wafer 1800 after the hydrogen implantation step. The wafer 1800 now comprises the top oxide layer 1902, and upper 1800A, and lower 1800B silicon layers, separated by a hydrogen implanted silicon layer 2002. In step 1708 the implanted, and oxidized side of the wafer 1800 is placed in contact with a second wafer 2102 of the kind depicted in FIG. 18, and the two wafers adhere by Van Der Waals forces to form a bonded wafer 2100. FIG. 21 is a sectional elevation of the wafer depicted in FIG. 20 contacting a second wafer. In step 1710 the bonded wafer is heated to about 500° C. The heating causes the defects caused by the hydrogen implantation and/or included hydrogen to coalesce thereby cleaving the wafer at about the predetermined average depth of the hydrogen implant. FIG. 22 is a SOI wafer 2200 obtained by cleaving the wafer shown in FIG. 21. The SOI wafer comprises the upper silicon layer 1800A, as an upper device layer, and the second wafer 2102 as a base, and the oxide layer 1902 interposed between the upper silicon layer 1800A and the second wafer 2102. In step 1712 the SOI wafer is given a high temperature anneal in an inert atmosphere at 1000° C. to 1300° C. for 30 minutes to 2 hours to improve bonding among the oxide layer and the second wafer 2102.

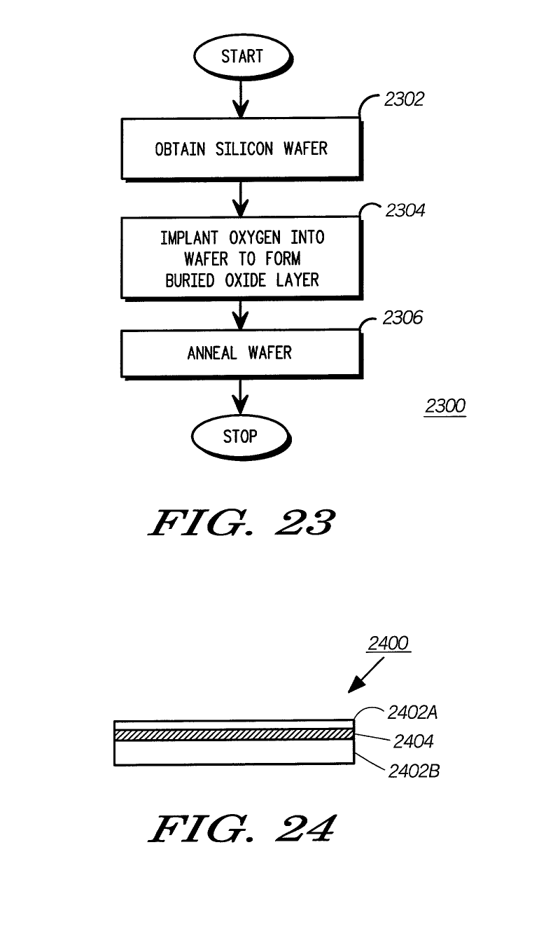

FIG. 23 is a flow chart of a second process 2300 of making a SOI wafer. In step 2302 a silicon wafer is obtained. In step 2304 the wafer is implanted with oxygen to form a buried oxide layer. In step 2306 the wafer is annealed to repair damage to the crystal structure caused by the implanting step.

FIG. 24 is a sectional elevation view of the SOI wafer 2400 made by the process shown in FIG. 23. The wafer 2400 comprises a silicon base 2402B, an oxide layer 2404 formed by oxygen implantation overlaying the silicon base 2402, and a top layer of silicon 2402A overlying the oxide layer 2404.

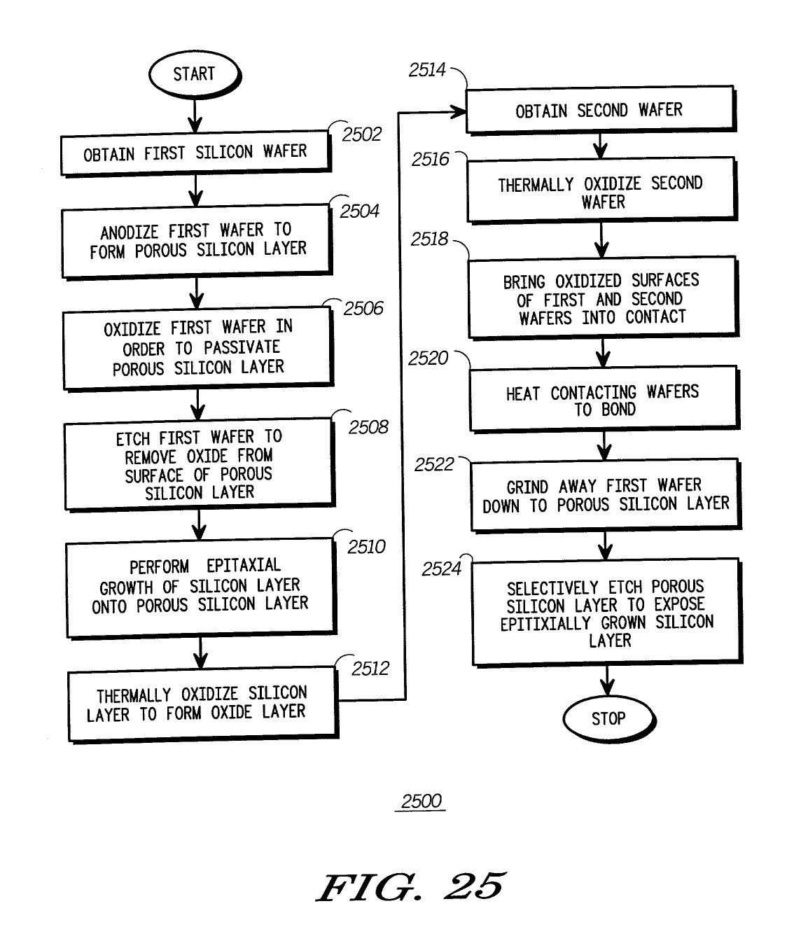

A third process 2500 for making a SOI wafer will presently be described with reference to FIGS. 25-27. The third process is a variant of the BESOI process mentioned above. Wafers manufactured by this process or similar processes are available from Canon U.S.A., Inc., of Lake Success, New York.

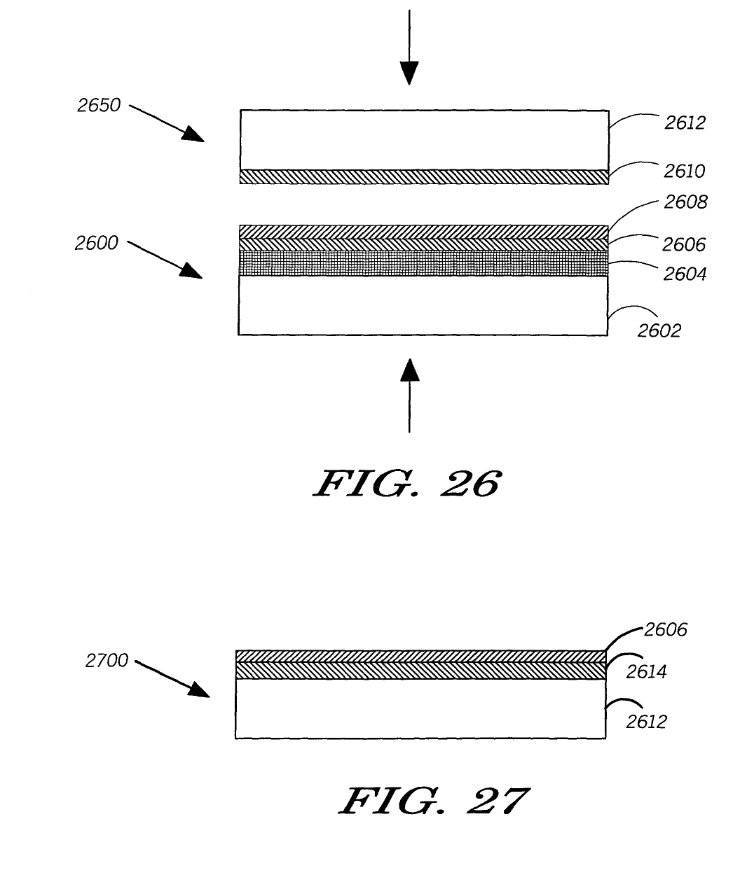

FIG. 25 is a flow chart of the third process 2500 of making a SOI wafer. FIG. 26 depicts sectional elevation views of two wafers produced and used in the process of making the SOI wafer shown in FIG. 25.

In step 2502 a first silicon wafer 2600 is obtained. At the start of process 2500, the first silicon wafer includes a first doped single crystal silicon disk 2602. The disk 2602 is P doped and has a resistivity of from about 0.01 to about 0.02 ohm-cm. In step 2504 the disk 2602 is anodized to form a porous silicon layer 2604 having a thickness of from about one to about ten microns. The wafer is anodized in a solution of a 49% Hydrofluoric acid solution and C21-1501-1 mixed in a two-to-one ratio using a current density of about 7 mA/CM². In step 2506 the first wafer 2600 is oxidized in order to passivate the porous silicon layer. According to an exemplary embodiment the wafer 2600 is oxidized in step 2508 by heating it to about 400° C. for about one hour in an oxygen atmosphere. In step 2508, the wafer is etched to remove the oxide from the surface of the porous silicon layer 2604. In step 2510 a nonporous silicon layer 2606 is epitaxially grown on the surface of the porous silicon layer 2604. The nonporous silicon layer 2606 is grown using Chemical Vapor Deposition (CVD) in which the wafer 2600 with the passivated porous silicon layer 2604 is heated to 900° C. in an 80 Torr ambient of dichlorosilane and Hydrogen. In step 2512 a first oxide layer 2608 is thermally grown on the nonporous silicon layer 2606.

In step 2514 a second wafer 2650 is obtained. Initially, the second wafer includes a second doped silicon disk 2612. In step 2516 the second wafer 2650 is thermally oxidized to form a second oxide layer 2610 on the second doped silicon disk 2612. In step 2518 the oxide layer 2610 of the second wafer 2650 and the oxide layer 2608 of the first wafer 2600 are brought into contact. In step 2520 the two contacting wafers 2600, 2650 are heated in order to cause a bond to form between the two oxide layers 2608, 2610 and produce a bonded wafer. In step 2522 the first disk of silicon 2602 is ground away to expose the porous silicon layer 2604. In step 2524 the porous silicon layer 2604 is selectively etched, to expose the nonporous silicon layer 2606. The porous silicon layer can be selectively etched using a mixture of 49% Hydrofluoric acid (HF) and 30% hydrogen peroxide (1-1202) in a 1:5 ratio.

FIG. 27 is a sectional elevation view of a SOI wafer 2700 produced by the process shown in FIG. 25. The SOI wafer 2700 includes the second doped silicon disk 2612 as a bulk layer. An oxide layer 2614 formed by bonding the oxide layer 2608 of the first wafer 2600 and the oxide layer 2610 of the second wafer 2650, is born on the second doped silicon disk 2612, and the nonporous silicon layer 2606 is born on the oxide layer 2614.

Processes that are suitable for producing MEMS resonators in bulk silicon wafers will presently be described. These processes employ deep trench etching techniques to form resonant structures that are aligned perpendicular to the surface of the wafer in which they are made. By achieving a MEMS resonator with perpendicular orientation, it is possible to greatly reduce the area of wafer required to accommodate a MEMS resonator. The latter economy in wafer area utilization reduces overall manufacturing costs for a device that employs a MEMS resonator.

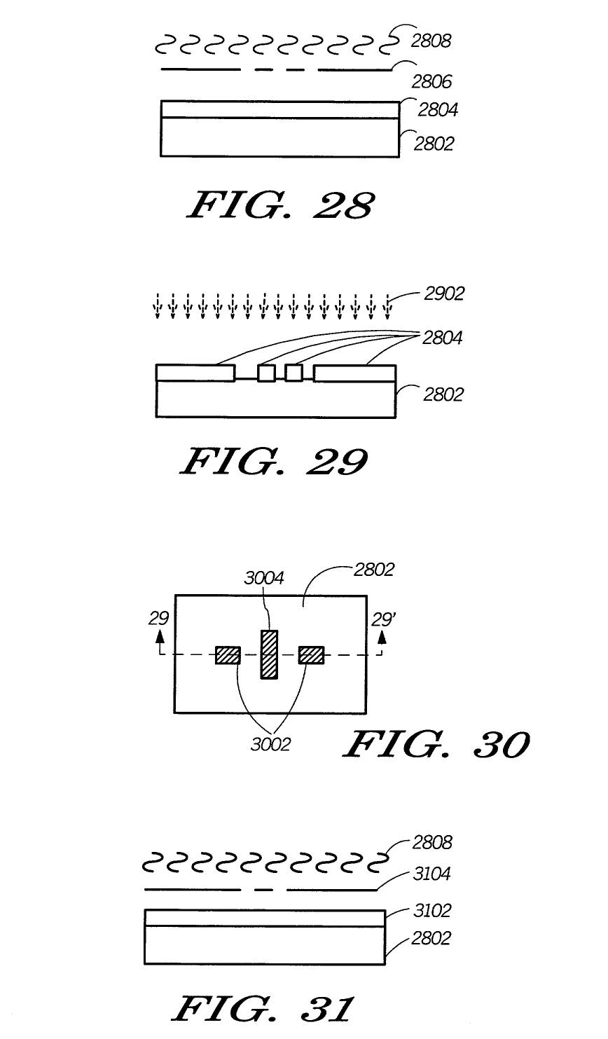

FIGS. 28 through 34 are a sequence of depictions of a section of a wafer at which a MEMS device is being fabricated at various stages in the fabrication. These views will be referred to in the following description of the fabrication process. Due to the great differences in size between a semiconductor wafer and the devices fabricated thereon, these views are not drawn to scale.

FIG. 28 is a sectional elevation view of a wafer 2806 bearing a first resist 2804 that is being exposed to patterning radiation 2808 using a first mask 2806 in a process for making a MEMS resonator.

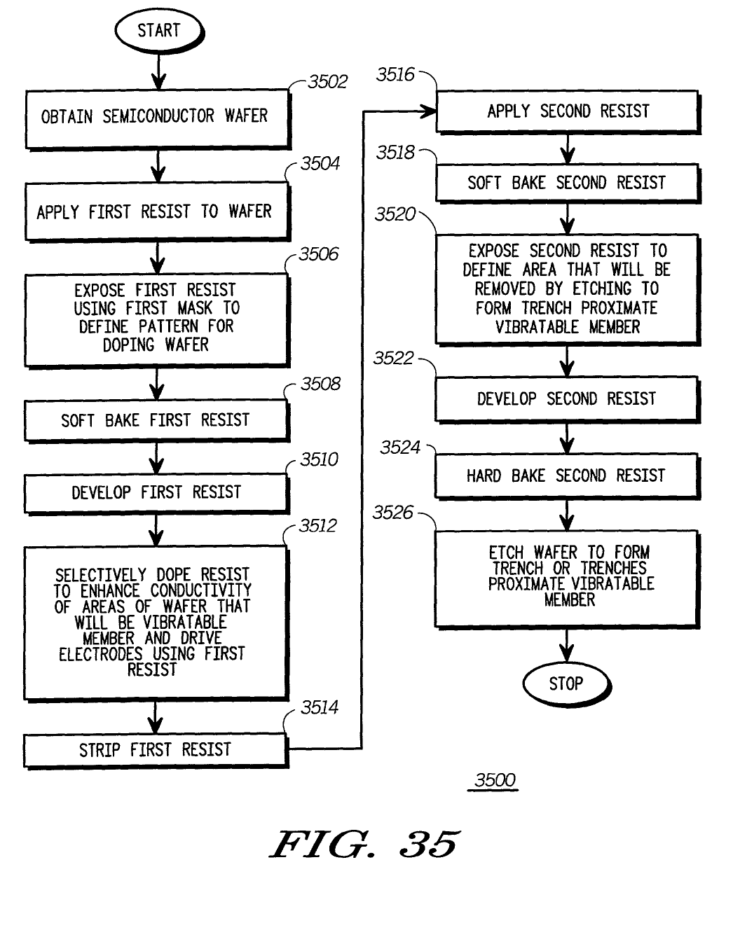

FIG. 35 is a flow chart of a process 3500 of making a MEMS resonator. In step 3502 the semiconductor wafer 2802 is obtained. In step 3504 the first resist 2804 is applied to the semiconductor wafer 2802. In step 3506 the first resist 2804 is imagewise exposed to radiant or corpuscular radiation 2808 using the first mask 2806. In step 3506 the first resist 2804 bearing wafer 2802 is soft baked to evaporate volatile solvents from the resist 2804. In step 3510 the first resist is developed. The resist 2804 can optionally be hard baked after the development step 3510.

FIG. 29 is a sectional elevation view of the wafer shown in FIG. 28 during a doping operation. The first resist 2804 is shown in a patterned condition in FIG. 29 after the development step 3510. Dopant atoms or ions 2902 are represented as vectors directed at the wafer 2802.

FIG. 30 is a plan view of the wafer shown in FIG. 29 showing doped areas. The section plane corresponding to FIG. 29 is indicated on FIG. 30.

In step 3512 the wafer 2802 is selectively doped to enhance the conductivity of selected areas. A first area 3004 that is doped will be located at the top of a vibrating member 3304 (FIGS. 33, 34). Two additional areas 3002 that are doped will be used as electrodes to exert electric forces on the vibrating member 3304 and capacitively couple signals to and from the vibrating member 3304 (FIGS. 33, 34).

FIG. 31 is a sectional elevation view of the wafer 2802 shown in FIG. 29 bearing a second resist 3102 that is being exposed to patterning radiation 2808.

In step 3514 the first resist 2804 is stripped from the wafer, and in step 3514 the second resist 3102 is applied to the wafer 2802. In step 3520 the second resist is soft baked. In step 3520 the second resist is imagewise exposed to radiant or corpuscular energy 2808 using a second mask 3104 in order to define areas for etching the wafer 2802.

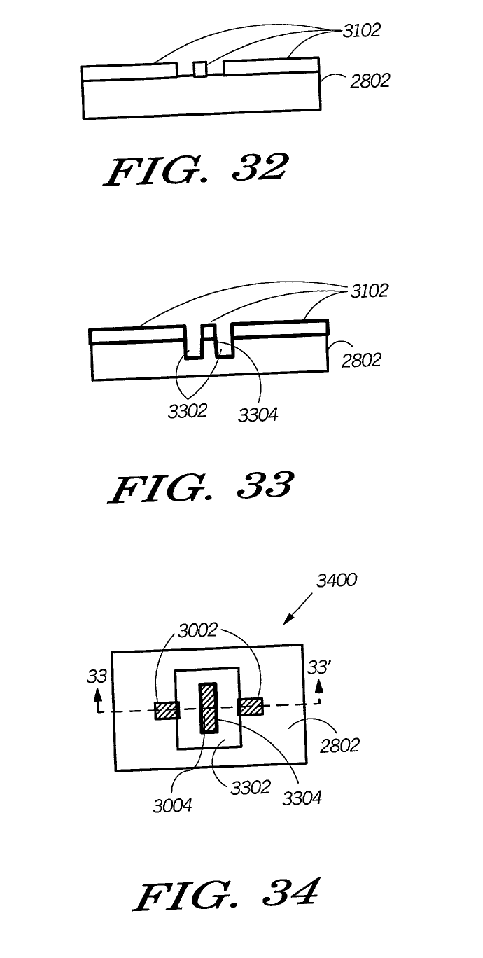

In step 3522 the resist is developed. FIG. 32 is a sectional elevation view of the wafer shown in FIG. 31 after development of the second resist. In FIG. 32 the second resist 3102 is seen in a patterned condition.

In step 3524 the second resist 3102 is hard baked. The step of hard baking makes the second resist 3102 more etch resistant so that over etching is reduced. In step 3526 the wafer 2802 is etched to form a trench 3302 (FIG. 33, 34) proximate to a vibrating member 3304 (FIGS. 33, 34). If desired, two or more trenches can be etched, rather than a single trench.

FIG. 33 is a sectional elevation view of the wafer shown in FIG. 32 after etching using the second resist, and FIG. 34 is a plan view of a MEMS resonator device 3400 showing doped areas 3002, 3004 and an etched rectangular trench 3302 surrounding a vibrating member 3304. The section plane used in FIG. 33 is indicated in FIG. 34. As seen in FIG. 34 a single closed curve, rectangular plan trench 3302 surrounds the vibrating member 3004.

The length of the vibrating member 3004 is the vertical dimension of the vibrating member 3304 in the plan view shown in FIG. 34. The width of the vibrating member 3304 is the horizontal dimension of the vibrating member 3304 in the plan view shown in FIG. 34. The height of the vibrating member 3304 is the vertical dimension of the vibrating member 3304 in the sectional elevation view of shown in FIG. 33. The depth of the trench 3302 is equal to the height of the vibrating member 3304. The ratio of the height of the vibrating member 3304 to the width of the vibrating member is preferably at least about five more preferably at least about ten. In order to achieve high ratios between the depth of the trench 3304 and its width, a reactive ion etcher (RIE) tool is preferably used to form the trench 3304. Reactive ion etchers are capable of etching trenches having aspect ratios of at least about fifty to one. Using deep trench etching allows long beam to be fabricated oriented perpendicularly to the wafer 2802 surface and occupy a small area of the wafer 2802. Additionally, by fabricating a vibrating member that is only attached to the wafer 2802 at its bottom, and making the vibration member long by using deep trench etching, a vibrating member with good Q can be obtained.

In operation the doped electrode areas 3002 can be used to connect the MEMS resonator 3400 to an external circuit such as an oscillator circuit in which the MEMS resonator serves as a frequency selective positive feedback element. In an oscillator circuit, one of the electrodes 3002 can be connected to the oscillators amplifier output, and the other could be connected to the oscillators amplifier input to provide a feedback pathway. The resonance mode of the vibrating member 3304 is the mode of a plate that is clamped at one end. The top of the vibrating member 3304 (visible in FIG. 34) will oscillate back and forth along an axis connecting the two doped electrode regions 3002. The vibrating member 3304 exhibits resonances at one or more selected frequencies that depend on its dimensions, and the material properties of the silicon wafer from which it is made. The dimensions of the vibrating members in this and other embodiments can be chosen to obtain a selected frequency of vibration using principles of solid mechanics analysis. A Finite Element Method (FEM) model based on solids mechanics principles can be used in selecting the dimensions of the vibrating member to obtain a selected frequency of vibration.

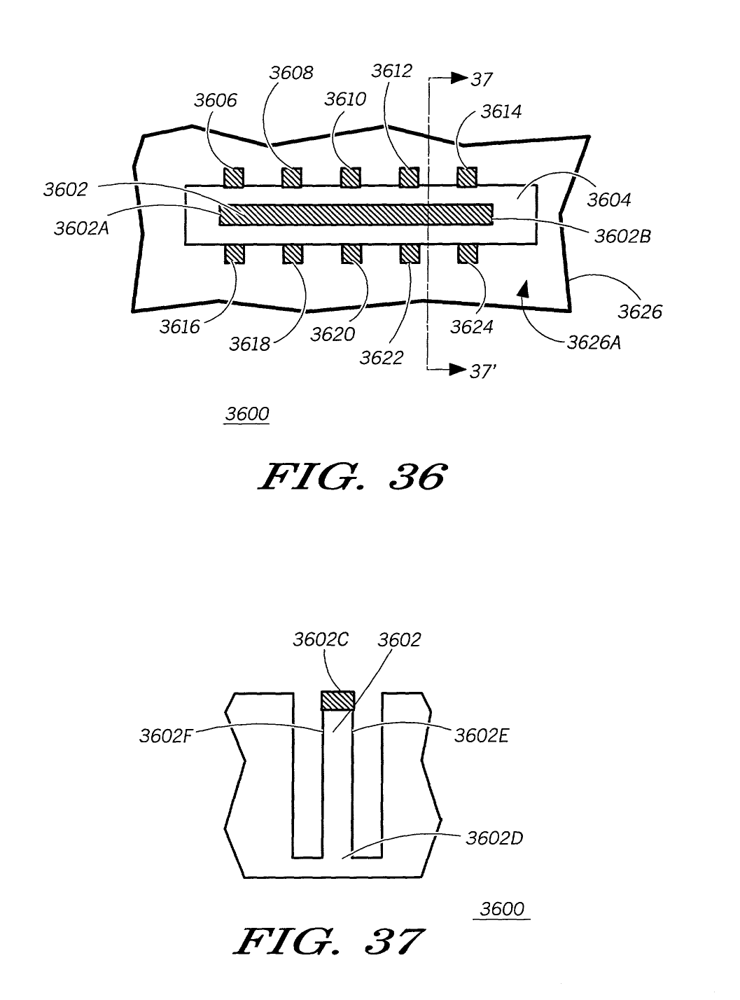

FIG. 36 is a fragmentary plan view of a MEMS 3600 resonator that has vibratable plate 3602 oriented perpendicular to a semiconductor chip surface 3626A. FIG. 37 is a sectional elevation view of the MEMS resonator 3600 shown in FIG. 36. The section plane of FIG. 37 is indicated in FIG. 36.

The MEMS resonator 3600 includes a vibrating plate 3602 that is dimensioned to support a vibration mode that includes five anti-nodes, and driven by five pairs of drive electrodes (including electrodes 3606-3624) to vibrate in the vibration mode. The resonator 3600 comprise deep trench 3604 etched in the surface 3626A of a semiconductor chip 3626. The plan of the deep trench 3604 follows a closed curve path, specifically a rectangular path. The closed curve deep trench bounds the vibrating plate 3602. The vibrating plate 3602 includes a first free side edge 3602A, a second free side edge 360213, a free top edge 3602C (FIG. 37), and a bottom edge 3602D (FIG. 37) that is connected to the semiconductor chip 3626. The vibrating plate 3602 further comprises a first face 3602E and a second face 3602F. The vibrating plate 3602 is perpendicular to the surface 3626A of the semiconductor chip 3626. In other words a vector normal to the first face 3602E is perpendicular to a vector normal to the surface 3626A of the semiconductor chip 3626. The top edge 3626C of vibrating plate 3602 is preferably selectively doped to increase its conductivity and thereby enhance its electric force interaction with the drive electrodes 3606-3624. The top edge 3626C is not selectively doped. In the latter case it is conductive due to the dopant present in the whole semiconductor chip 3626.

Five drive electrodes 3606-3614 are arranged from left to right in a row on one side of the trench 3604 (top side in FIG. 36) opposite the vibrating plate 3602. Five more drive electrodes 3616-3624 are arranged from left to right on an opposite side of the trench 3604 (bottom side in FIG. 37) opposite the vibrating member 3602. The drive electrodes 3606-3624 are preferably formed by selectively doping the semiconductor chip 3626. Pairs of electrodes that are directly across the vibrating plate 3602 from each other have opposite electrical phases. For example the first electrode 3606 in the top row 3606, and the first electrode 3616 in the bottom row 3616 would differ in phase by 7 π radians. Also each electrode has an opposite electrical phase compared to electrodes that are directly adjacent to it on the same side of the vibrating plate 3602. Thus the electrical phase of the first electrode 3606 on the top row 3606 would differ by Pi radians from the second electrode 3608 on the top row 3608. In operation as the vibrating plate 3602 vibrates in a mode with anti-nodes corresponding to the positions of the electrodes 3606-3624, it will induce electrical signals in the electrodes 3606-3624 with the relative phasing just mentioned. On the other hand if electrical signals with the relative phasing mentioned are applied to the electrodes 3606-3624 the signals will induce the vibrating plate 3602 to vibrate in the mode with anti-nodes corresponding the positions of the electrodes. The doping of the top edge 3602C of the vibrating plate 3602C aids in the interaction with the electrodes 3606-3614. As discussed above with reference to the resonators shown in FIGS. 13-16, the resonator shown in FIGS. 36-37 and other resonators discussed below can be coupled to external circuits in more than one alternative ways. With reference to the resonator 3600 shown in FIG. 36, one connection topology is to connect all the electrodes having one phase to one side of an external circuit, and to connect all the other electrodes that are at opposite phase to the other side of the electrical circuit.

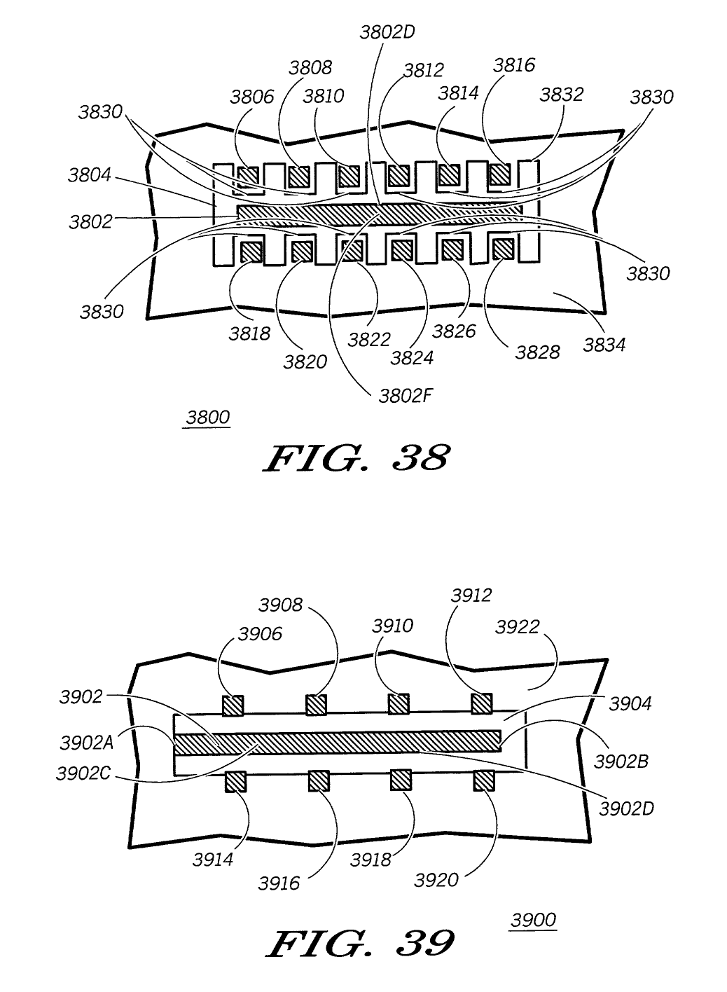

FIG. 38 is a fragmentary plan view of a third MEMS resonator 3800 which has a corrugated trench wall 3832. The resonator 3800 is fabricated in the surface of a semiconductor chip 3834. The resonator 3800 includes a vibrating plate 3802 that has a bottom edge 3802D connected to the semiconductor chip 3834. The vibrating plate 3802 is rectangular in shape, and its three edges other than from the bottom edge are free. The top edge 3802 of the vibrating plate 3802 is doped to enhance its electric field interaction with the electrodes 3806-3828. The corrugated wall 3832 that is etched in the semiconductor chip 3834 surrounding the vibrating plate 3802, includes a number of inwardly projecting corrugations 3830. A plurality of electrodes 3806-3828 that are made by X selectively doping regions of the semiconductor chip 3834 are located on the inwardly projected corrugations 3830 of the corrugated wall 3832. The inwardly projecting corrugations 3830 aid in electrically isolating the electrodes 3806-3828 from each other. The electrodes 3806-3828 are arranged in two rows of six. A first row includes six electrodes 3806-3816 spaced along one side (top side in FIG. 38) of the resonator 3800, facing the vibrating plate 3802. A second row includes six more electrodes 3818-3828 spaced along a second side (bottom side in FIG. 38) of the resonator 3800, facing the vibrating plate 3802. The electrical phase of every other electrode in each row is the same. Adjacent electrodes within a row have phases that are radians apart (i.e., opposite phases). Electrodes that are across the vibrating plate 3802 from each other also have opposite phases. The vibrating plate 3820 vibrates in a mode that has six anti-nodes and five nodes. One node is located at the longitudinal center 3802F of the vibrating plate 3820.

The vibrating plate 3802, since it is symmetric as judged from its longitudinal center 3802F, vibrates in a mode that has a node at its center, and vibrates in a mode that is anti-symmetric as judged from its center. Accordingly, the effects of external jarring can be minimized by connecting a first set of electrodes that has a first electrical phase to one input of a differential circuit (e.g., input of a differential amplifier) and connecting a second set of electrodes that has a phase opposite to that of the first set of electrodes to a second input of the differential circuit. When the resonator is jarred, the vibrating plate 3802 will tend to pick up a motion that is symmetric in contrast to its anti-symmetric vibration mode. The motion caused by jarring will cause common mode signals to be induced in the electrodes that will be rejected by the differential circuit.

FIG. 39 is a fragmentary plan view of a MEMS resonator 3900 that includes a vibrating plate with two clamped edges. This MEMS resonator 3900 has a open curve, specifically a U-shaped deep trench 3904 in a semiconductor chip 3926, partially (on three side) surrounding a vibrating member 3902. The vibrating plate 3902 has two edges clamped, i.e., connected to the semiconductor chip 3922. A first side edge 3902A, and a bottom edge 3902D are connected to the semiconductor chip. A top edge 3902C and a second side edge 3902B are free. The vibrating plate 3902 is dimensioned to vibrate in a mode that includes four anti-nodes. Four electrodes 3906-3912 are arranged in a first row along one side (top side in FIG. 39) of the trench 3904. Four more electrodes 3914-3920 are arranged in a second row along a second side (lower side in FIG. 39) of the trench 3904. One electrode from each of the rows is located adjacent to each of the four anti-nodes. The electrodes adjacent to each anti-node, (one from each row) have opposite electrical phases. Within a row the electrical phase of the electrodes changes by half a cycle from one electrode to the next. The top edge 3902C of the vibrating plate 3902 is preferably doped so that the vibrating plate 3902 interacts with the electrodes 3906-3920 via electric force interaction.

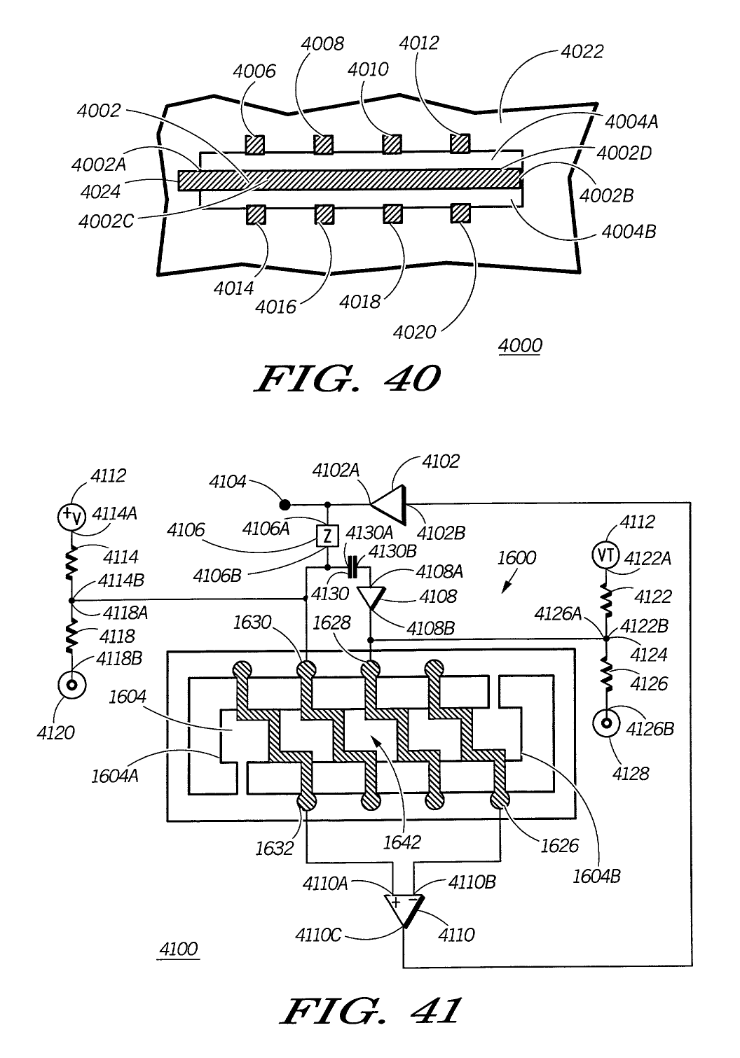

FIG. 40 is a fragmentary plan view of a MEMS resonator 4000 that includes a vibrating plate 4002 with three clamped edges. The resonator 4000 is fabricated in a semiconductor chip 4022 and includes a vibrating plate 4002 bounded by a first deep trench 4004A on one side (top side in FIG. 40) and a second deep trench 4004B on a another side (bottom side in FIG. 40). The vibrating plate 4002 is clamped (i.e., connected to the silicon chip 4022) at a first side edge 4002A, a second side edge 400213, and a bottom edge 4002D. The top edge 4002C is free. Four electrodes 4006-4012 are arranged in a row on the semiconductor chip 4022 along the side of the first deep trench 4004A opposite the vibrating plate 4002. Four more electrodes 4014-4020 are arranged in a row on the semiconductor chip 4022 along the side of the second deep trench 4004B opposite the vibrating plate 4002. The eight electrodes 4006-4020 are preferably formed by selectively doping the semiconductor chip 4022. The top edge 4002C of the plate 4002 is preferably also doped to enhance its electric field interaction with the electrodes 4006-4020. The doped region of the top plate extends to a contact area 4024 beyond the side edge 4002A of the plate 4002. The vibrating plate 4002 is dimensioned to vibrate in a mode that has four anti-nodes. One electrode from each row is positioned at the longitudinal position of one of the anti-nodes. The two electrodes positioned at each anti-node have opposite electrical phases. Within each row the electrical phase increases by half a cycle from one electrode in the row to the next.

FIG. 41 is a schematic of an oscillator 4100 using the MEMS resonator 1600 shown in FIG. 16. An oscillator amplifier 4102 has an output 4102A coupled to an output terminal 4104 and to an input 4106A of an impedance network 4106. The impedance network 4106 can consist of a resistor. The impedance network serves to adjust the amplitude and optionally the phase of a fed back portion of the output of the oscillator amplifier 4102. The impedance network has an output 4106B coupled to a first doped conductive region 1630 of the resonator 1600, and to a first terminal 4130A of a DC blocking capacitor 4130. A second terminal 4130B of the DC blocking capacitor 4130 is coupled to an input 4108A of a unity gain inverting amplifier 4108. An output 4108B of the unity gain inverting amplifier 4108 is coupled to a second doped conductive region 1628 of the resonator 1600.

Voltage dividers are used to bias the output of the signals output by the impedance network 4106, and the unity gain inverting amplifier 4108. A first voltage divider that is used to bias the output of the impedance network 4106 comprises a top resistor 4114 including a top terminal 4114A coupled to a voltage source 4112, and a bottom terminal 4114B coupled to a first voltage divider midpoint 4116. A bottom resistor 4118 includes a top terminal coupled to the first voltage divider midpoint 4116, and a bottom terminal 4118B coupled through a first via 4120 to the silicon base layer 202 (FIG. 16). The midpoint 4116 of the first voltage divider is coupled to the output 4106B of the impedance network 4106.

A second voltage divider that is used to bias the output 4108B of the unity gain inverting amplifier 4108 comprises a top resistor 4122 that includes a top terminal 4122A coupled to the voltage source 4112, and a second terminal 4122B coupled to a second voltage divider midpoint 4124. The second voltage divider further comprises a bottom resistor 4126 that includes a top terminal 4126A coupled to the second voltage divider midpoint 4124, and a bottom terminal coupled through a second via 4128 to silicon base layer 202 (FIG. 16). The second voltage divider midpoint is coupled to the output 4108B of the inverting unity gain amplifier 4108.

Biasing the first conductive region 1630, and the second conductive region 1628 using the first and second voltage dividers establishes an attractive force between the resonant member 1604, and the silicon base layer 202 (FIG. 16). In operation of the oscillator, the attractive force will be modulated by periodic signals applied to the first and second conductive region 1630, 1628. The modulation of the attractive force, drives the flexural beam mode of the resonant member 1604.

The beam 1604 supports a transverse flexural vibration mode that has a first anti-node over which the first doped region crosses and a second anti-node over which the second doped region crosses. The first and second anti-nodes are located immediately adjacent (with no other intervening anti-nodes) and on opposite sides of the center 1642 of the beam 1604. The first and second anti-nodes have opposite phase, that is, they move in opposite directions (when one is deflected up the other is deflected down). Connecting the first doped region 1630 with the output of the impedance network 4106 directly, while driving the second doped region 1628 with the output of the unity gain inverting amplifier 4106 will drive the above mentioned flexural vibration mode.

A non-inverting input 411OA of a differential amplifier 4110 is coupled to a third doped region 1632 of the resonator 1600. An inverting input 411 OB of the differential amplifier 4110 is coupled to a fourth doped region 1626 of the resonator 1600. The third doped conductive 1632 region crosses an anti-node located adjacent the first end 1604A of the beam 1604. The fourth doped region 1626 crosses an anti-node adjacent to the second end 1604B of the beam 1604. An output 411C of the differential amplifier 4110 is coupled to an input 4102B of the oscillator amplifier 4102.

The impedance network 4106, unity gain inverting amplifier 4108, resonator 1600, and differential amplifier 4110 form a regenerative feedback path for the oscillator amplifier 4102. A portion of an output signal of the amplifier oscillator 4102 is fed back through the regenerative feedback path to the input 4102B of the oscillator amplifier 4102 causing it to output a periodic signal. In operation a periodic signal, i.e., the feed back signal, will pass through the resonator.

As discussed above differential signal connections to the resonator, such as shown in FIG. 41, are useful in lessening the effects of jarring motion on the output of the oscillator 4100.

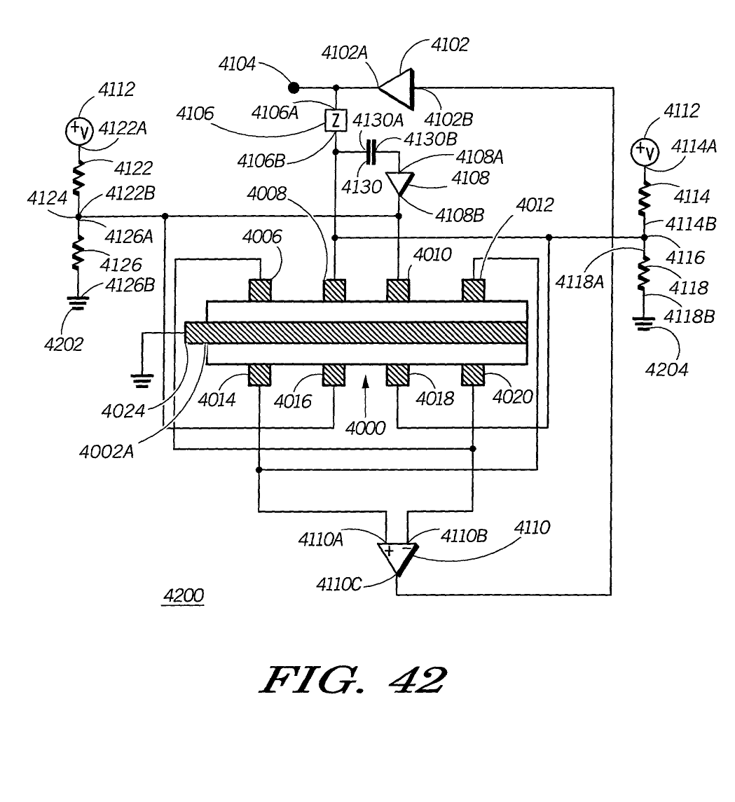

FIG. 42 is a schematic of an oscillator 4200 using the MEMS resonator 4000 shown in FIG. 40. The circuit elements other than the resonator 4000 are the same as shown in FIG. 41. Reference is made to the preceding description of FIG. 41 for a description of those circuit elements. The coupling of the resonator 4000 of FIG. 40 to the oscillator circuit is as follows. The output 4106B of the impedance network is coupled to a first electrode 4008, and a second electrode 4018. The first electrode 4008 is located on the first side (top side in FIG. 42) of the resonator 4000 at the longitudinal position of a first anti-node of the vibration mode of the vibrating plate 4002. The second electrode 4018 is located on the second side (bottom side in FIG. 42) of the resonator 4000 at the longitudinal position of a second anti-node. The first and second anti-nodes have opposite phase which is to say when one is deflects up (from the perspective shown in FIG. 42) the other deflects down. The output 4108B of the unity gain inverting amplifier 4108B is coupled to a third electrode 4010, and a fourth electrode 4016. The third electrode is located on the first side of the resonator 4000, adjacent to the first electrode 4008, and across from the second electrode 4018, i.e., at the longitudinal position of the second anti-node. The fourth electrode 4016 is located on the second side of the resonator 4000, adjacent to the second electrode 4018, and across from the first electrode 4008, i.e., at the longitudinal position of the first anti-node.

In the oscillator 4200, the bottom terminal 4118B of the bottom resistor 4118 of the first voltage divider, the bottom terminal 4126B of the bottom resistor of the second voltage divider, and the extension of the doped region 4024 are grounded to the semiconductor chip 4022.

In operation the first 4008 and second 4018 electrodes will receive the fed back signal at a first phase, and the third 4010, and fourth 4016 electrodes will receive the fed back signal at a second phase that differs from the first phase by one-hundred and eighty degrees.

The non-inverting input 4110A of the differential amplifier 4110 is coupled to a fifth electrode 4014 and a sixth electrode 4012. The fifth electrode 4014 is located on the second side of the resonator 4000, adjacent to the fourth electrode 4016, on the side of the first side edge 4002A of the vibrating plate 4002. The sixth electrode 4012 is located on the first side of the resonator 4000, adjacent to the third electrode 4010, on the side of the second side edge 4002B of the vibrating plate 4002. The inverting input 4110B of the differential amplifier 4110 is coupled to a seventh electrode 4020, and an eighth electrode 4006. The seventh electrode 4020 is located on the second side of the resonator 4002 adjacent to the second electrode 4018 across from the sixth electrode 4012. The eighth electrode 4006 is located on the first side of the resonator 4002, adjacent to the first electrode 4008 and across from the fifth electrode 4014.

The sixth 4012 and seventh 4020 electrodes correspond in position to a third anti-node of the vibration of the vibrating plate 4002 that has the same phase as the first anti-node. The fifth 4014 and eighth 4006 electrodes correspond in position to a fourth anti-node of the vibration of the vibrating plate that has the same phase as the second anti-node.

In operation the resonator 4000 serves as a frequency selective positive feedback element in the feedback signal path of the oscillator 4200. The resonator 4000 sets the frequency of the oscillator at the frequency corresponding to the mode of vibration of the vibrating plate 4002 that has anti-nodes positioned consistent with the positioning and phasing of the electrodes 4006-4002.

II. Monocrystalline Semiconductor Structures And Devices

Utilizing Compliant Substrates

In addition to monocrystalline silicon structures and devices such as SOI wafers, the invention has found immediate application in the field of high-quality monocrystalline semiconductor structures and devices which utilize compliant substrates. A wide variety of semiconductor and semiconductor compound materials can be employed.

For purposes of illustration and not limitation, further examples of semiconductor structures and devices, and of their fabrication, useful in carrying out the invention, will now be given. Referring to FIG. 43, a schematic illustration of a semiconductor structure 20 is shown in cross section. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

Structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. An amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II (A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

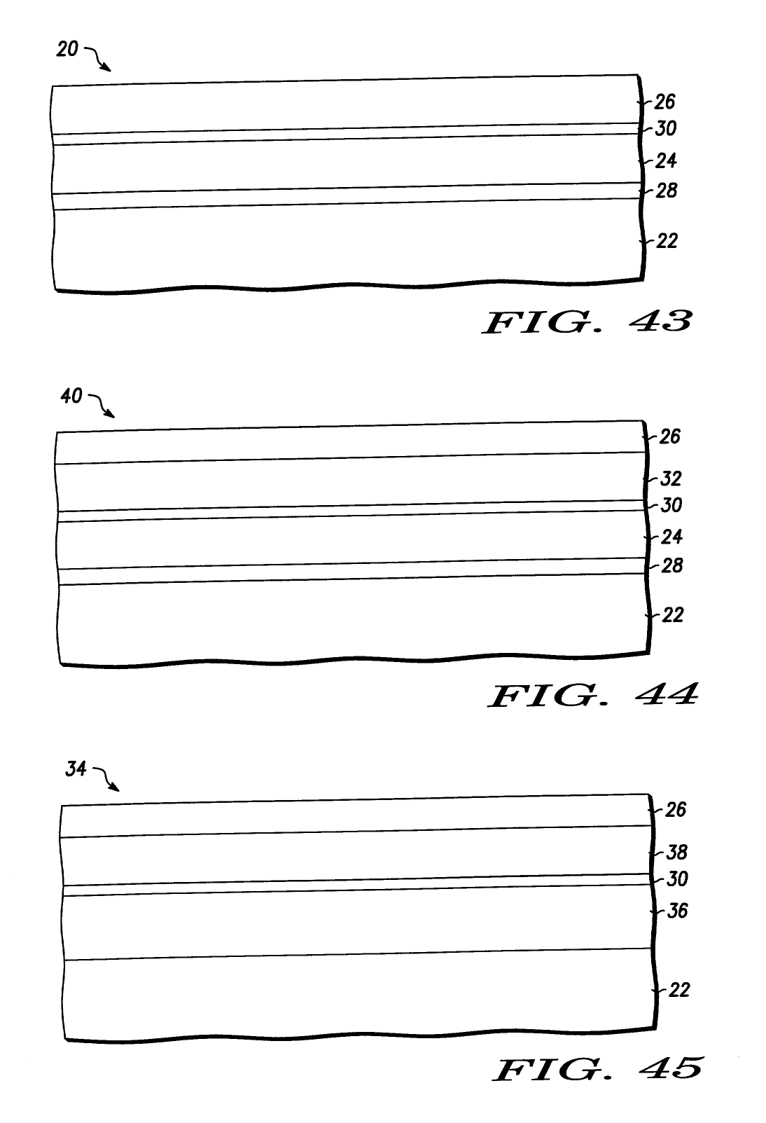

FIG. 44 illustrates, in cross section, a portion of a semiconductor structure 40 which is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 45 schematically illustrates, in cross section, a portion of another exemplary semiconductor structure 34. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 43 and 44 are adequate for growing monocrystalline material layers over a monocrystalline substrate. However, the process described in connection with FIG. 45, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

An additional monocrystalline layer 38 may serve as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

An additional monocrystalline layer 38 comprises monocrystalline material (e.g., a material discussed above in connection with monocrystalline layer 26) that is thick enough to form devices within layer 38. In this case, a semiconductor structure does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34. These examples are merely illustrative, and it is not intended that the invention be limited to these illustrative examples.

### EXAMPLE 1

A monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this exemplary embodiment, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this exemplary embodiment monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further exemplary embodiment monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700° C. The lattice structure of the resulting crystalline oxide exhibits a 45° rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1110 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45° rotation with respect to the accommodating buffer layer lattice structure and a lattice mismatch to (100) InP of less than 2.5%, and preferably less than about 1.0%.

### EXAMPLE 3

In accordance with a further exemplary embodiment a structure is provided that is suitable for the growth of an epitaxial film of a monocrystalline material comprising II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This is an example of structure 40 illustrated in FIG. 44. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an Ina_{y} superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 44. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The additional buffer layer 32, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 45. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g. layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. Layer 38 includes the same materials as those comprising layer 26. For example, if layer 26 includes GaAs, layer 38 also includes GaAs. However, in accordance with other embodiments of the invention, layer 38 may include materials different from those used to form layer 26. In accordance with one example, layer 38 is about 1 monolayer to about 100 nm thick.

Referring again to FIGS. 43-45, substrate 22 is a monocrystalline substrate such as a monocrystalline silicon or gallium arsenide substrate. The crystalline structure of the monocrystalline substrate is characterized by a lattice constant and by a lattice orientation. In a similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

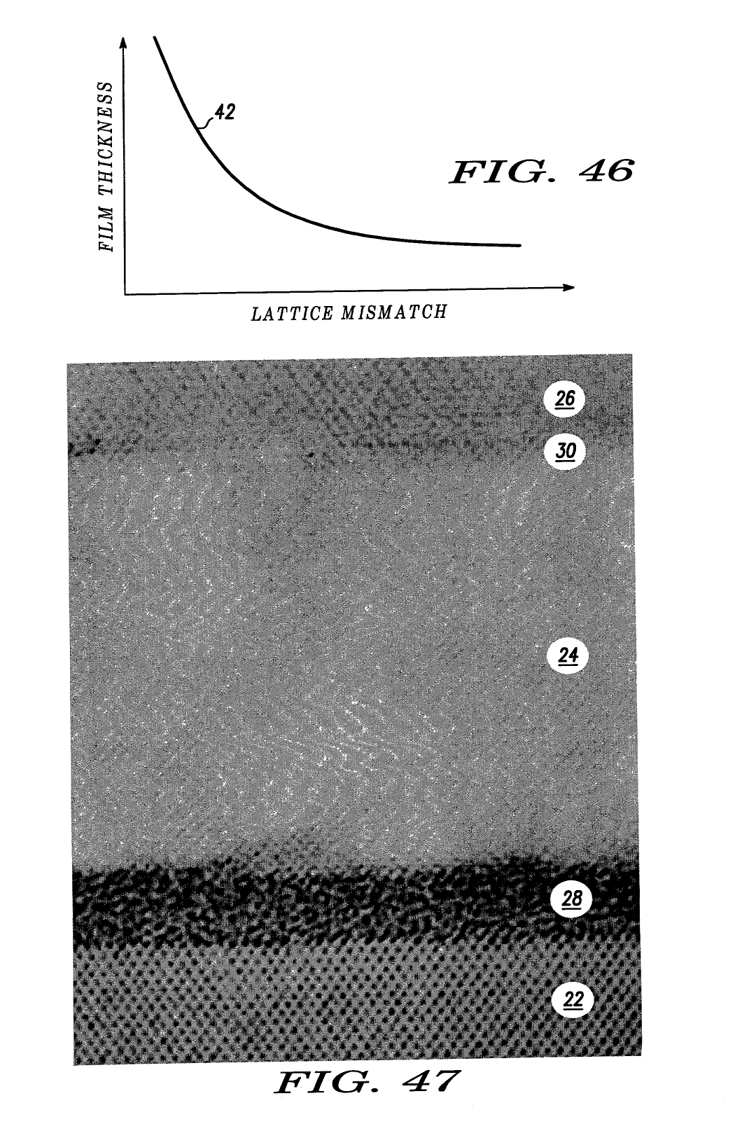

FIG. 46 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

Substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, a high quality, thick, monocrystalline titanate layer is achievable. Still referring to FIGS. 43-45, layer 26 is a layer of epitaxially grown monocrystalline material and that crystalline material is also characterized by a crystal lattice constant and a crystal orientation. The lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process for fabricating a semiconductor structure such as the structures depicted in FIGS. 43-45. The process starts by providing a monocrystalline semiconductor substrate comprising silicon or germanium. The semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×l structure forms a template for the ordered growth of an overlying layer of a monocrystalline oxide. The template provides the necessary chemical and physical properties to nucleate the crystalline growth of an overlying layer.

The native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×l structure with strontium, oxygen, and silicon remaining on the substrate surface. Again, this forms a template for the subsequent growth of an ordered monocrystalline oxide layer.

Following the removal of the silicon oxide from the surface of the substrate, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 47 is a high resolution Transmission Electron Micrograph (TEM) of a semiconductor material in which a single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

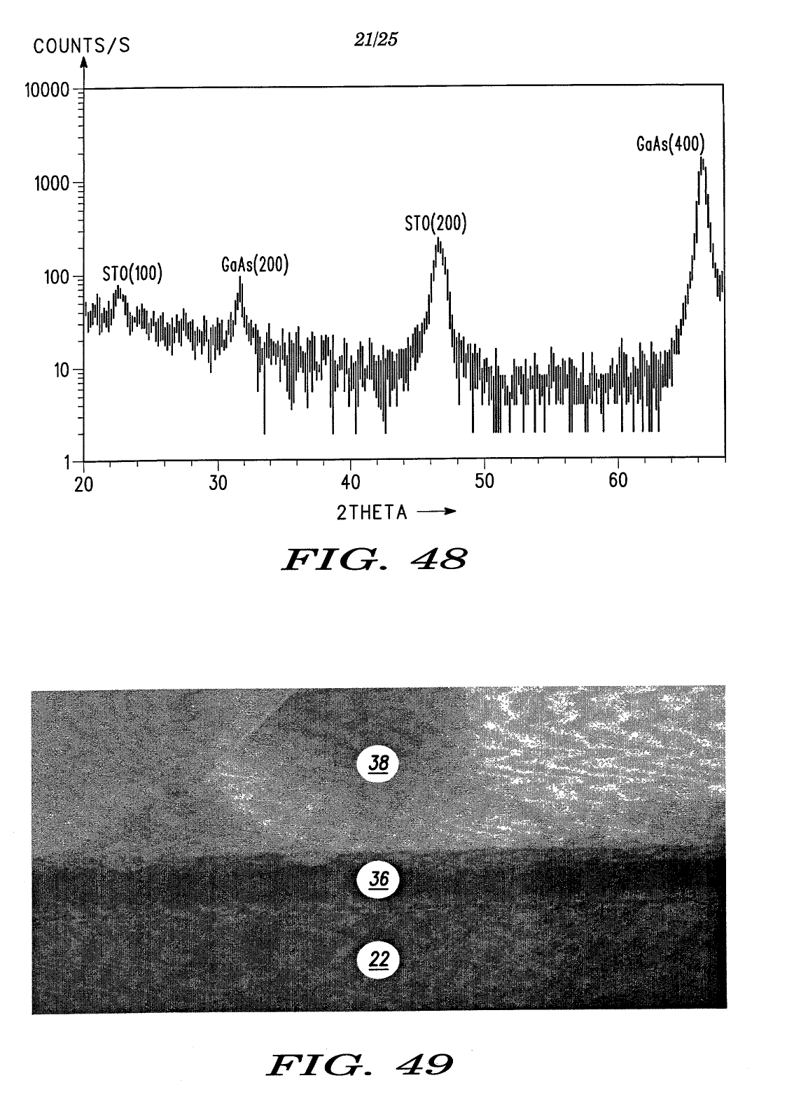

FIG. 48 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 44 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 45, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 49 is a high resolution TEM of a semiconductor material in which a single crystal SrTiO₃ accommodating buffer layer was grown epitaxially on silicon substrate 22. During this growth process, an amorphous interfacial layer form as described above. Next, additional monocrystalline layer 38 comprising a compound semiconductor layer of GaAs is formed above the accommodating buffer layer and the accommodating buffer layer is exposed to an anneal process to form amorphous oxide layer 36.

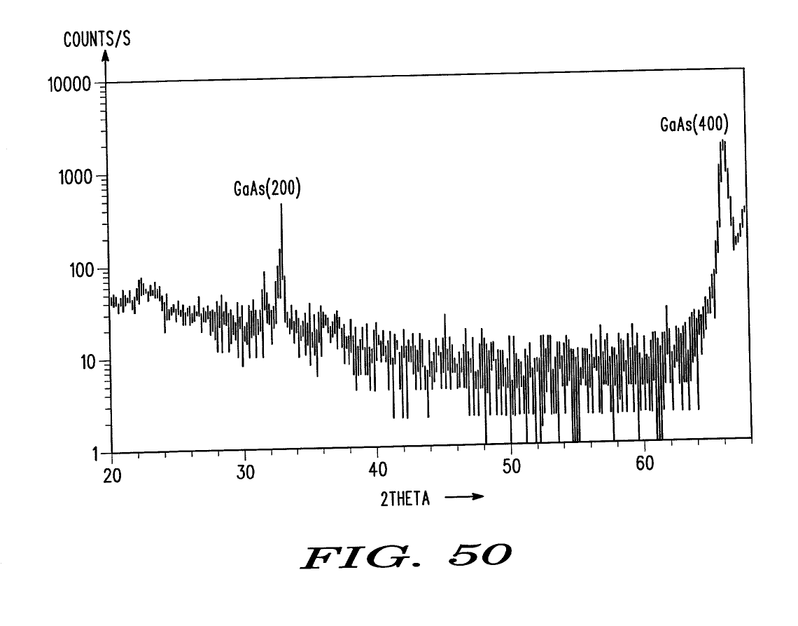

FIG. 50 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50° indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

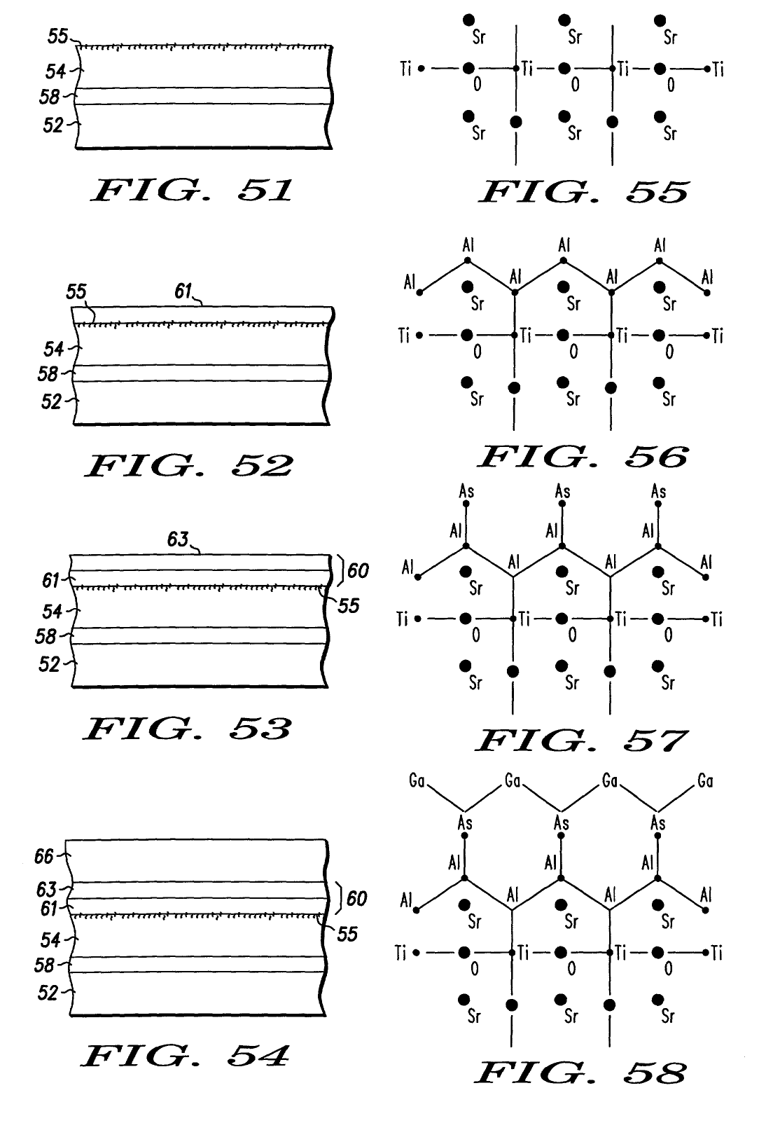

The formation of one exemplary device structure is illustrated schematically in cross section in FIGS. 51-54. Like the previously described examples, referred to in FIGS. 43-45, this example involves the process of forming a compliant substrate utilizing the epitaxial growth of single crystal oxides, such as the formation of accommodating buffer layer 24 previously described with reference to FIGS. 43 and 44 and amorphous layer 36 previously described with reference to FIG. 45, and the formation of a template layer 30. However, the embodiment illustrated in FIGS. 51-54 utilizes a template that includes a surfactant to facilitate layer-by-layer monocrystalline material growth.

Turning now to FIG. 51, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 43-44 and any of those compounds previously described with reference to layer 36 in FIG. 45 which is formed from layers 24 and 28 referenced in FIGS. 43 and 44.

Layer 54 is grown with a strontium (Sr) terminated surface represented in FIG. 51 by hatched line 55 which is followed by the addition of a template layer 60 which includes a surfactant layer 61 and capping layer 63 as illustrated in FIGS. 52 and 53. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 52 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 53. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, C VD, MOCVD, MEE, ALE, PVD, CSD, PLD, and the like to form the final structure illustrated in FIG. 54.

FIGS. 55-58 illustrate possible molecular bond structures for a specific example of a compound semiconductor structure illustrated in FIGS. 51-55. More specifically, FIGS. 55-58 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 43 and 44, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAs)}

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 52-54, to increase the surface energy of the monocrystalline oxide layer 54 and also to shift the crystalline structure of the template to a diamond-like structure that is in compliance with the original GaAs layer.

FIG. 55 illustrates the molecular bond structure of a strontium terminated surface of a strontium titanate monocrystalline oxide layer. An aluminum surfactant layer is deposited on top of the strontium terminated surface and bonds with that surface as illustrated in FIG. 56, which reacts to form a capping layer comprising a monolayer of Al₂Sr having the molecular bond structure illustrated in FIG. 56 which forms a diamond-like structure with an sp³ hybrid terminated surface that is compliant with compound semiconductors such as GaAs. The structure is then exposed to As to form a layer of AlAs as shown in FIG. 57. GaAs is then deposited to complete the molecular bond structure illustrated in FIG. 58 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

Turning now to FIGS. 59-62, the formation of another device structure is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 59. Monocrystalline oxide layer 74 may be comprised of any of those materials previously discussed with reference to layer 24 in FIGS. 43 and 44, while amorphous interface layer 78 is preferably comprised of any of those materials previously described with reference to the layer 28 illustrated in FIGS. 43 and 44. Substrate 72, although preferably silicon, may also comprise any of those materials previously described with reference to substrate 22 in FIGS. 43-45.

Next, a silicon layer 81 is deposited over monocrystalline oxide layer 74 via MBE, CVD, MOCVD, MEE, ALE, PVD, CSD, PLD, and the like as illustrated in FIG. 60 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphous the monocrystalline oxide layer 74 into a silicate amorphous layer 86 and carbonize the top silicon layer 81 to form capping layer 82 which in this example would be a silicon carbide (SiC) layer as illustrated in FIG. 61. The formation of amorphous layer 86 is similar to the formation of layer 36 illustrated in FIG. 45 and may comprise any of those materials described with reference to layer 36 in FIG. 45 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this example possesses a one step formation of the compliant substrate containing a SiC top surface and an amorphous layer on a Si surface. More specifically, this example uses an intermediate single crystal oxide layer that is amorphosized to form a silicate layer which adsorbs the strain between the layers. Moreover, unlike past use of a SiC substrate, this example is not limited by wafer size which is usually less than 50 mm in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

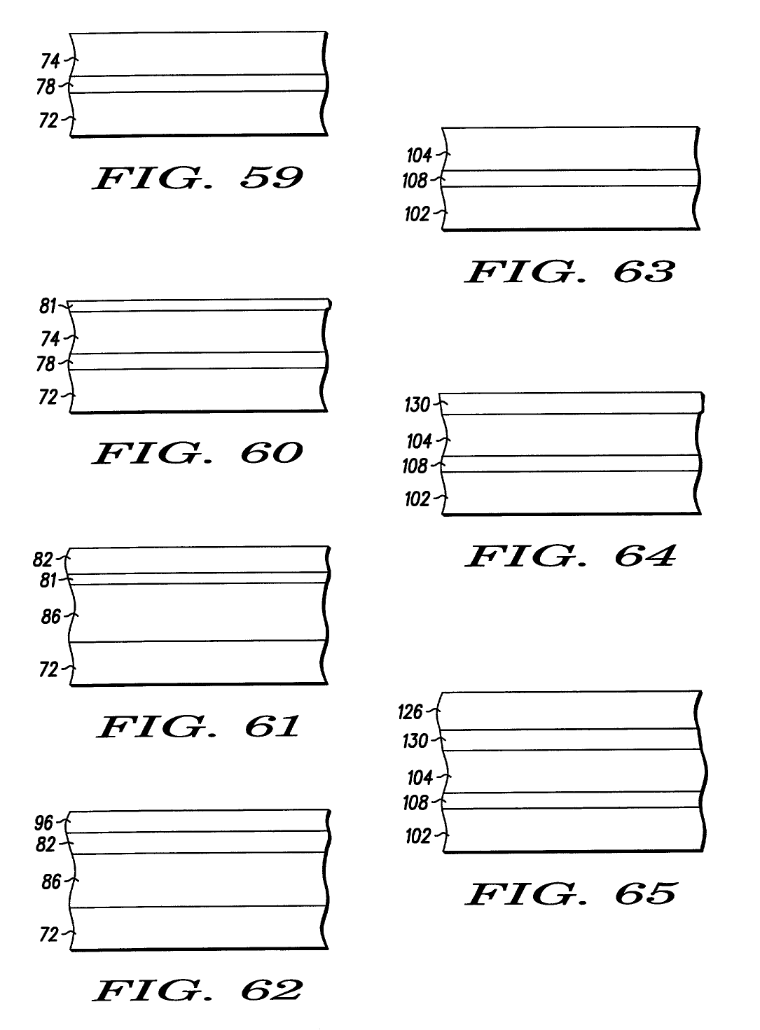

FIGS. 63-65 schematically illustrates, in cross section, the formation of another example of a preferred device structure. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 63 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 43 and 44. Amorphous interface layer 108 may comprise any of those materials previously described with reference to amorphous interface layer 28 in FIGS. 43 and 44. Substrate 102 is preferably silicon but may also comprise any of those materials previously described with reference to substrate 22 in FIGS. 43-45.

A template layer 130 is deposited over accommodating buffer layer 104 as illustrated in FIG. 64 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂.

A monocrystalline material layer 126 is epitaxially grown over template layer 130 to achieve the final structure illustrated in FIG. 65. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate preferred examples and not limit the invention. Other combinations are possible. For example, structures and methods for fabricating material layers which form semiconductor structures, devices and integrated circuits can include other layers such as metal and non-metal layers, as well as structures and methods for forming a compliant substrate which is used in the fabrication of semiconductor structures, devices and integrated circuits and the material layers suitable for fabricating those structures, devices, and integrated circuits. With the invention, it is now simpler to integrate MEMS resonators and other devices that include monocrystalline layers comprising semiconductor and compound semiconductor materials as well as other material layers that are used to form those devices with other components that work better or are easily and/or inexpensively formed within semiconductor or compound semiconductor materials. This allows a MEMS resonator or other device to be shrunk, the manufacturing costs to decrease, and yield and reliability to increase.

A monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all operationally active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g., conventional compound semiconductor wafers).

III. Electromechanical Resonating Devices Implemented with Monocrystalline Semiconductor Structures And Devices

Utilizing Compliant Substrates

Two general examples of electromechanical resonating devices implemented according to principles of the invention will now be given. In a first example, features of a semiconductor structure include a monocrystalline silicon substrate, an amorphous oxide material overlying the monocrystalline silicon substrate, and a monocrystalline perovskite oxide material overlying the amorphous oxide material. A monocrystalline compound semiconductor material overlies the monocrystalline perovskite oxide material. Optional, additional features include (a) a template layer between the monocrystalline perovskite oxide layer and the monocrystalline compound semiconductor material, (b) a buffer material of monocrystalline semiconductor material form between the monocrystalline perovskite oxide material and the monocrystalline compound semiconductor material and (c) a template layer may also be formed between the monocrystalline perovskite oxide material and a buffer material. The monocrystalline compound semiconductor material layer is patternwise etched to define a resonating member capable of resonating in a vibrational mode, and one or more supports mechanically coupled to the resonating member. Preferably, the monocrystalline compound semiconductor material layer is selectively doped to define one or more conductive pathways onto the resonating member. A portion of the semiconductor structure beneath the monocrystalline compound semiconductor material layer is etched, preferably to free the resonating member for electromechanical resonance.

In a second example, a semiconductor structure has features which include a monocrystalline substrate characterized by a first lattice constant and a monocrystalline insulator layer having a second lattice constant different than the first lattice constant overlies the monocrystalline substrate. An amorphous oxide layer is located between the monocrystalline substrate and the monocrystalline insulator layer. A monocrystalline compound semiconductor layer having a third lattice constant different than the first lattice constant overlies the monocrystalline insulator layer. The second lattice constant is selected to be either equal to the third lattice constant or intermediate the first and third lattice constant. The semiconductor structure features may also include a template layer between the monocrystalline insulator layer and the monocrystalline compound semiconductor layer. Further, optional additional features may include a buffer layer between the monocrystalline insulator layer and the monocrystalline compound semiconductor layer. The monocrystalline compound semiconductor layer is patternwise etched to define a resonating member capable of resonating in a vibrational mode, and one or more supports mechanically coupled to the resonating member. Preferably, the monocrystalline compound semiconductor layer is selectively doped to define one or more conductive pathways onto the resonating member. A portion of the semiconductor structure beneath the monocrystalline compound semiconductor material layer is etched, preferably to free the resonating member for electromechanical resonance.

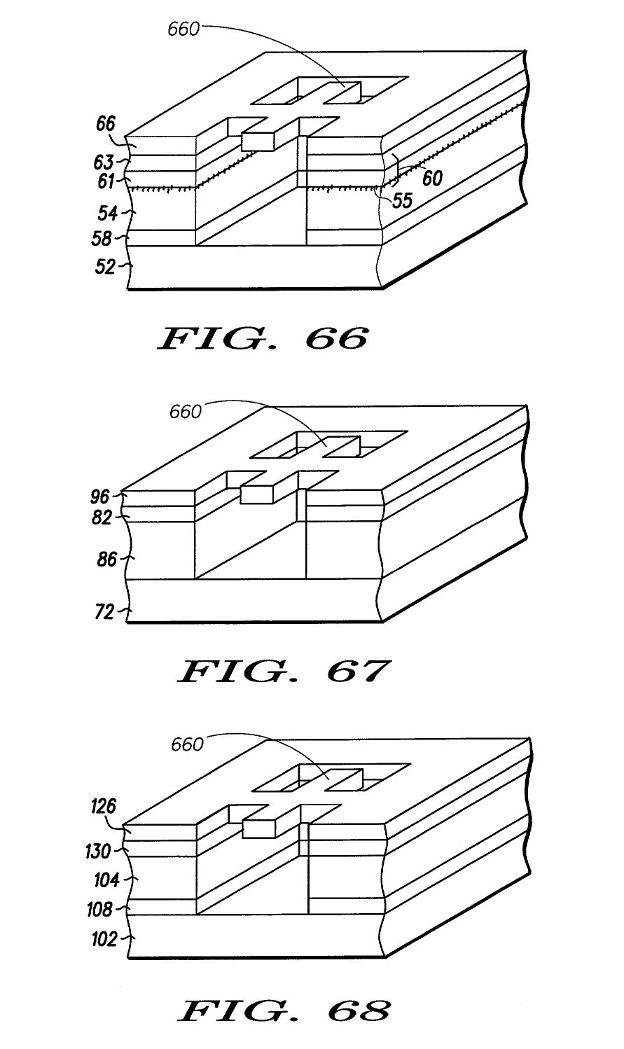

FIGS. 66, 67, and 68 recreate the structures described by FIGS. 54, 62, and 65 respectively in a perspective view along with a resonating member 660 patternwise etched into the compound semiconductor layer of the structures in accordance with the present invention. Resonating member 660 may be configured in a variety of ways as discussed previously. The monocrystalline compound semiconductor material layer is patternwise etched to define a resonating member capable of resonating in a vibrational mode, and one or more supports mechanically coupled to the resonating member 660. A portion of the semiconductor structure beneath the monocrystalline compound semiconductor material layer is etched. Though the structures in FIGS. 66, 67, and 68 are illustrated as being etched down to the substrate (52, 72, 102), it is also possible to leave some of the intermediate layers in place as long as the resonating member is given enough room to vibrate freely.

In the above specific examples of high-quality monocrystalline structures utilizing compliant substrates, additional processing is carried out to implement electromechanical resonating devices according to principles of the present invention. The monocrystalline semiconductor layer or compound semiconductor layer is patternwise etched to define a resonating member capable of resonating in a vibrational mode, and one or more supports mechanically coupled to the resonating member. Conventional electrical circuit connections are made to the resonating member. Preferably, the monocrystalline compound semiconductor layer is selectively doped to conveniently provide one or more conductive pathways onto the resonating member. One or more portions of the semiconductor structure beneath the monocrystalline compound semiconductor material layer are etched, preferably to provide clearance to allow the resonating member to undergo vibrational electromechanical resonance.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure including an electromechanical resonating device, comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material; and
a resonating device formed in the monocrystalline compound semiconductor material, including a resonating member capable of resonating in a vibrational mode, and one or more supports mechanically coupled to the resonating member.

2. The semiconductor structure of claim 1 wherein at least a portion of the semiconductor structure below the resonating member is etched to provide a clearance region to allow the resonating member to undergo vibrational resonance.

3. The semiconductor structure of claim 1 wherein the resonating member comprises a selectively doped vibrating member.

4. The semiconductor structure according to claim 3 wherein the selectively doped vibrating member comprises a beam shaped member having a first end, and a second end, a first longitudinal side extending between the first end and the second end, and a second longitudinal side extending between the first end and the second end.

5. The semiconductor structure according to claim 4 wherein the selectively doped vibrating member is capable of resonating in a vibrational mode that includes the first node and a second node, and the resonating device further comprises a second support attached at the second node.

6. The semiconductor structure according to claim 5 wherein a first doped conducting region extends from the first support to the second support.

7. The semiconductor structure according to claim 5 wherein:
the first support is attached to the first longitudinal side;
the second support is attached to the second longitudinal side; and
the device further comprises a third support attached to the second longitudinal side at the first node and a fourth support attached to the first longitudinal side at the second node.

8. The semiconductor structure according to claim 4 wherein:
the first node is located at approximately a center of the beam shaped member;
the first support is attached at approximately a center of the first longitudinal side of the beam shaped member;
a first doped conducting region extends from the first support towards the first end of the beam shaped member; and
the resonating device further comprises:
a second support attached at approximately the center of the second longitudinal side of the beam shaped member;
a second doped conducting region extending from the second support toward the second end of the beam shaped member; and
an insulating region between the first doped conducting region and the second doped conducting region.

9. The semiconductor structure according to claim 8 wherein the selectively doped vibrating member is capable of resonating in a vibrational mode that includes the first node, a second node, and a third node and the resonating device further comprises a third support attached to the beam at the second node and a fourth support attached to the beam at the third node.

10. The semiconductor structure according to claim 8 wherein the first doped conducting region extends from the first support to the third support, and the second doped conducting region extends from the second support to the fourth support.

11. The semiconductor structure of claim 1 further comprising a template layer formed between the monocrystalline perovskite oxide material and the monocrystalline compound semiconductor material.

12. The semiconductor structure of claim 1 further comprising a buffer material of monocrystalline semiconductor material formed between the monocrystalline perovskite oxide material and the monocrystalline compound semiconductor material.

13. The semiconductor structure of claim 1 wherein the monocrystalline compound semiconductor material is selected from the group consisting of: III-V compounds, mixed III-V compounds, II-VI compounds, and mixed II-VI compounds.

14. The semiconductor structure of claim 1 wherein the monocrystalline compound semiconductor material is selected from the group consisting of: GaAs, AlGaAs, InP, InGaAs, InGaP, ZnSe, AlInAs, CdS, CdHgTe, and ZnSeS.

15. A semiconductor structure including an electromechanical resonating device, comprising:
a monocrystalline substrate characterized by a first lattice constant;
a monocrystalline insulator layer having a second lattice constant different than the first lattice constant overlying the monocrystalline substrate;
an amorphous oxide layer between the monocrystalline substrate and the monocrystalline insulator layer;
a monocrystalline compound semiconductor layer having a third lattice constant different than the first lattice constant overlying the monocrystalline insulator layer;
the second lattice constant selected to be one of (a) equal to the third lattice constant and (b) intermediate the first and third lattice constant; and
a resonating device formed in the monocrystalline compound semiconductor layer, including a resonating member capable of resonating in a vibrational mode, and one or more supports mechanically coupled to the resonating member.

16. The semiconductor structure of claim 15 wherein the amorphous oxide layer has a thickness sufficient to relieve strain in the monocrystalline insulator layer.

17. The semiconductor structure of claim 15 further comprising a template layer between the monocrystalline insulator layer and the monocrystalline compound semiconductor layer.

18. The semiconductor structure of claim 15 further comprising a buffer layer between the monocrystalline insulator layer and the monocrystalline compound semiconductor layer.

19. The semiconductor and or structure of claim 15 wherein the monocrystalline substrate is characterized by a first crystalline orientation and the monocrystalline insulator layer is characterized by a second crystalline orientation and wherein the second crystalline orientation is rotated with respect to the first crystalline orientation.

20. The semiconductor structure of claim 15 wherein at least a portion of the semiconductor structure below the resonating member is etched to provide a clearance region to allow the resonating member to undergo vibrational resonance.

21. The semiconductor structure of claim 15 wherein the resonating member comprises a selectively doped vibrating member.

22. The semiconductor structure according to claim 21 wherein the selectively doped vibrating member comprises a beam shaped member having a first end, and a second end, a first longitudinal side extending between the first end and the second end, and a second longitudinal side extending between the first end and the second end.

23. The semiconductor structure according to claim 22 wherein the selectively doped vibrating member is capable of resonating in a vibrational mode that includes the first node and a second node, and the resonating device further comprises a second support attached at the second node.

24. The semiconductor structure according to claim 23 wherein a first doped conducting region extends from the first support to the second support.

25. The semiconductor structure according to claim 23 wherein:
the first support is attached to the first longitudinal side;
the second support is attached to the second longitudinal side; and
the device further comprises a third support attached to the second longitudinal side at the first node, and a fourth support attached to the first longitudinal side at the second node.

26. The semiconductor structure according to claim 22 wherein:
the first node is located at approximately a center of the beam shaped member;
the first support is attached at approximately a center of the first longitudinal side of the beam shaped member;
a first doped conducting region extends from the first support towards the first end of the beam shaped member; and
the resonating device further comprises:
a second support attached at approximately the center of the second longitudinal side of the beam shaped member;
a second doped conducting region extending from the second support toward the second end of the beam shaped member; and
an insulating region between the first doped conducting region and the second doped conducting region.

27. The semiconductor structure according to claim 26 wherein the selectively doped vibrating member is capable of resonating in a vibrational mode that includes the first node, a second node, and a third node, and the resonating device further comprises a third support attached to the beam at the second node and a fourth support attached to the beam at the third node.

28. The semiconductor structure according to claim 26 wherein the first doped conducting region extends from the first support to the third support and the second doped conducting region extends from the second support to the fourth support.

29. The semiconductor structure of claim 15 further comprising a template layer formed between the monocrystalline perovskite oxide material and the monocrystalline compound semiconductor layer.

30. The semiconductor structure of claim 15 further comprising a buffer material of monocrystalline semiconductor material formed between the monocrystalline perovskite oxide material and the monocrystalline compound semiconductor layer.

31. The semiconductor structure of claim 15 wherein the monocrystalline compound semiconductor layer is selected from the group consisting of: III-V compounds, mixed III-V compounds, II-VI compounds, and mixed II-VI compounds.

32. The semiconductor structure of claim 15 wherein the monocrystalline compound semiconductor layer is selected from the group consisting of: GaAs, AlGaAs, InP, InGaAs, InGaP, ZnSe, AlInAs, CdS, CdHgTe, and ZnSeS.

33. A process for fabricating a semiconductor structure including an electromechanical resonating device, comprising:
providing a monocrystalline silicon substrate having a first lattice constant;
selecting a material that when properly oriented has a second lattice constant and crystalline structure such that the material can be deposited as a monocrystalline film overlying the monocrystalline silicon substrate, the second lattice constant being different than the first lattice constant;
depositing a monocrystalline film of the material overlying the monocrystalline silicon substrate, the film having a thickness less than a thickness of the material that would result in strain-induced defects, the monocrystalline film being strained because the first lattice constant is different than the second lattice constant;
forming an amorphous interface layer at an interface between the monocrystalline film and the monocrystalline silicon substrate, the amorphous interface layer having a thickness sufficient to relieve the strain in the monocrystalline film;
selecting a compound semiconductor material having a third lattice constant that is different than the first lattice constant and that when properly oriented can be deposited on the monocrystalline film as a monocrystalline compound semiconductor layer;
epitaxially depositing a monocrystalline layer of the compound semiconductor layer overlying the monocrystalline film;
selecting the second lattice constant to be one of (a) intermediate to the first and third lattice constants and (b) equal to the third lattice constant; and
patternwise etching the compound semiconductor layer to define a resonating member capable of resonating in a vibrational mode and one or more supports mechanically coupled to the resonating member.

34. The process of claim 33 further comprising the step of etching a portion of the semiconductor structure beneath the resonating member to provide a clearance region to allow the resonating member to undergo vibrational resonance.

35. The process of claim 33 further comprising the step of selectively doping the compound semiconductor layer to the fine at least one conductive pathway to the resonating member.

36. The method according to claim 33 wherein the step of patternwise etching comprises the sub-step of patternwise etching the compound semiconductor layer to define a beam coupled to one or more supports.

37. The method according to claim 33 wherein the step of patternwise etching comprises the sub-steps of patternwise etching the compound semiconductor layer to define a beam comprising:
a first end edge at a first end of the beam;
a second end edge at a second end of the beam;
a first longitudinal edge extending between the first end and the second end; and
a second longitudinal edge extending between the first end and the second end; and
a central region.

38. The method according to claim 37 wherein the step of patternwise etching comprises the sub-steps of patternwise etching the compound semiconductor layer to define a first support coupled to the first longitudinal edge at a first point that is approximately midway between the first end and the second end and a second support coupled to the second longitudinal edge at a second point that is approximately midway between the first end and the second end.

39. The method according to claim 38 wherein the step of selectively doping the compound semiconductor layer comprises the step of selectively doping the compound semiconductor layer to define a first conductive region that extends from the first support towards the first end, and a second conductive region that extends from the second support towards the second end, and an isolation region between the first conductive region and the second conductive region.

40. The method according to claim 38 wherein the step of selectively doping the compound semiconductor layer comprises the step of selectively doping the compound semiconductor layer to define:
a first conductive region that extends from the first support to the first end;
a second conductive region that extends from the second support to the second end; and
an isolation region between the first conductive region and the second conductive region.

41. The method according to claim 37 wherein the step of patternwise etching comprises the sub-steps of patternwise etching the compound semiconductor layer to define a first support coupled to the first longitudinal edge at a first node of the vibrational mode, a second support coupled to the first longitudinal edge at a second node of the vibrational mode, a third support coupled to the second longitudinal edge at the first node of the vibrational mode, and a fourth support coupled to the second longitudinal edge at the second node of the vibrational mode.

42. The method according to claim 41 wherein the step of selectively doping the compound semiconductor layer comprises the step of selectively doping the compound semiconductor layer to define a first conductive region that extends from the first support at least towards the central region of the beam.

43. The method according to claim 41 wherein the step of selectively doping the compound semiconductor layer comprises the step of selectively doping the compound semiconductor layer to define a first conductive region that extends from the first support across the central region of the beam to the second support.

44. The process of claim 33, following the formation of the amorphous interface layer, further comprising the step of continuing to deposit the monocrystalline film of the material overlying the monocrystalline silicon substrate.

45. The process of claim 33 further comprising forming a first template layer overlying the monocrystalline silicon substrate to nucleate depositing the monocrystalline film.

46. The process of claim 45 further comprising forming a second template layer overlying the monocrystalline film to nucleate epitaxially depositing the monocrystalline layer.

47. The process of claim 33 wherein the depositing a monocrystalline film comprises epitaxially growing a monocrystalline oxide layer lattice-matched to the monocrystalline silicon substrate.

48. A process for fabricating a semiconductor structure comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film; and
patternwise etching the compound semiconductor layer to define a resonating member capable of resonating in a vibrational mode and one or more supports mechanically coupled to the resonating member.

49. The process of claim 48 further comprising the steps of etching a portion of the semiconductor structure beneath the resonating member to provide a clearance region to allow the resonating member to undergo vibrational resonance.

50. The process of claim 48 further comprising the steps of selectively doping the compound semiconductor layer to define at least one conductive pathway to the resonating member.

51. The method according to claim 48 wherein the step of patternwise etching comprises the sub-step of patternwise etching the compound semiconductor layer to define a beam coupled to one or more supports.

52. The method according to claim 48 wherein the step of patternwise etching comprises the sub-steps of patternwise etching the compound semiconductor layer to define a beam comprising:
a first end edge at a first end of the beam;
a second end edge at a second end of the beam;
a first longitudinal edge extending between the first end and the second end;
a second longitudinal edge extending between the first end and the second end; and
a central region.

53. The method according to claim 52 wherein the step of patternwise etching comprises the sub-steps of patternwise etching the compound semiconductor layer to define a first support coupled to the first longitudinal edge at a first point that is approximately midway between the first end and the second end, and a second support coupled to the second longitudinal edge at a second point that is approximately midway between the first end and the second end.

54. The method according to claim 53 wherein the step of selectively doping the compound semiconductor layer comprises the step of selectively doping the compound semiconductor layer to define a first conductive region that extends from the first support towards the first end, a second conductive region that extends from the second support towards the second end, and an isolation region between the first conductive region and the second conductive region.

55. The method according to claim 53 wherein the step of selectively doping the compound semiconductor layer comprises the step of selectively doping the compound semiconductor layer to define a first conductive region that extends from the first support to the first end, a second conductive region that extends from the second support to the second end, and an isolation region between the first conductive region and the second conductive region.

56. The method according to claim 52 wherein the step of patternwise etching comprises the sub-steps of patternwise etching the compound semiconductor layer to define a first support coupled to the first longitudinal edge at a first node of the vibrational mode, a second support coupled to the first longitudinal edge at a second node of the vibrational mode, a third support coupled to the second longitudinal edge at the first node of the vibrational mode, and a fourth support coupled to the second longitudinal edge at the second node of the vibrational mode.

57. The method according to claim 56 wherein the step of selectively doping the compound semiconductor layer comprises the step of selectively doping the compound semiconductor layer to define a first conductive region that extends from the first support at least towards the central region of the beam.

58. The method according to claim 56 wherein the step of selectively doping the compound semiconductor layer comprises the step of selectively doping the compound semiconductor layer to define a first conductive region that extends from the first support across the central region of the beam to the second support.

59. The process of claim 48, following the formation of the amorphous interface layer, further comprising the step of continuing to deposit the monocrystalline film of the material overlying the monocrystalline silicon substrate.

60. The process of claim 48 further comprising forming a first template layer overlying the monocrystalline silicon substrate to nucleate depositing the monocrystalline film.

61. The process of claim 60 further comprising forming a second template layer overlying the monocrystalline film to nucleate epitaxially depositing the monocrystalline layer.

62. The process of claim 48 wherein the depositing of a monocrystalline film comprises epitaxially growing a monocrystalline oxide layer lattice-matched to the monocrystalline silicon substrate.

63. A method for fabricating a semiconductor structure comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film; and
etching at least one deep trench in the compound semiconductor layer to define a resonating member capable of resonating in a vibrational mode and one or more supports mechanically coupled to the resonating member.

64. The method of claim 63 wherein the etching step defines a resonating member in the form of a vibrating plate.

65. The method of claim 64 wherein the compound semiconductor layer has a surface and the vibrating plate is oriented perpendicular to the surface.

66. The method according to claim 63 wherein the step of etching comprises the sub-steps of etching a first deep trench in the surface, and etching a second deep trench in the surface parallel to the first deep trench.

67. The method according to claim 63 wherein the step of etching comprises the sub-step of etching a closed curve plan trench in the surface.

68. The method according to claim 63 wherein the step of etching comprises the sub-step of etching a rectangular plan trench in the surface.

69. The method according to claim 63 wherein the step of etching comprises the sub-step of etching an open curve plan trench in the surface.

70. The method according to claim 63 wherein the step of etching comprises the sub-step of etching a U-shaped plan trench in the surface.

71. The method according to claim 63 further comprising the step of doping the vibrating plate.

72. The method according to claim 63 wherein the step of etching comprises the sub-step of reactive ion etching one or more deep trenches in the wafer to define a vibrating plate oriented perpendicular to the surface.

73. The method according to claim 63 further comprising the step of selectively doping a region peripheral to the vibrating plate.
